(19) United States
(12) Patent Application Publication
(10) Pub. No.: US 2011/0254052 A1
(43) Pub. Date: Oct. 20, 2011

(54) Hybrid Group IV/III-V Semiconductor Structures

(75) Inventors: John Kouvetakis, Mesa, AZ (US); Jose Menendez, Tempe, AZ (US)

(73) Assignee: Arizona Board of Regents, a body corporate acting for and on behalf of Arizona State University, Scottsdale, AZ (US)

(21) Appl. No.: 13/062,304

(22) PCT Filed: Sep. 16, 2009
(86) PCT No.: PCT/US09/57213

§ 371 Date: Jul. 6, 2011

Related U.S. Application Data
(60) Provisional application No. 61/105,670, filed on Oct. 15, 2008.

(51) Int. Cl. H01L 29/12; H01L 21/20

(52) U.S. Cl. 257/190; 438/478; 257/183; 257/616; 257/E29.068; 257/E21.09

(57) ABSTRACT

Described herein are semiconductor structures comprising (i) a Si substrate; (ii) a buffer region formed directly over the Si substrate, wherein the buffer region comprises (a) a Ge layer having a threading dislocation density below about 10⁵ cm⁻²; or (b) a Ge₁₋ₓSnₓ layer formed directly over the Si substrate and a Ge_{1-x-y}SiₓSn_{y} layer formed over the Ge₁₋ₓSnₓ layer; and (iii) a plurality of III-V active blocks formed over the buffer region, wherein the first III-V active block formed over the buffer region is lattice matched or pseudomorphically strained to the buffer region. Further, methods for forming the semiconductor structures are provided and novel Ge_{1-x-y}SiₓSn_{y}, alloys are provided that are lattice matched or pseudomorphically strained to Ge and have tunable band gaps ranging from about 0.80 eV to about 1.4O eV.

### CROSS-REFERENCE TO RELATED APPLICATIONS

This application claims the benefit of the filing date of U.S. Provisional Application Ser. No. 61/105,670, filed Oct. 15, 2008, which is hereby incorporated by reference in its entirety.

### STATEMENT OF GOVERNMENT FUNDING

The invention described herein was made in part with government support under grant number FA9550-60-01-0442, awarded by the US-AFOSR and the Department of Energy under Grant No. DE-FG36-08GO1800. The United States Government has certain rights in the invention.

### FIELD OF THE INVENTION

The invention generally relates to semiconductor structures comprising Group IV and III-V semiconductor layers. In particular, the invention relates to the use of such structures as active components in solar cell designs.

### BACKGROUND OF THE INVENTION

Monolithic multijunction solar cells have recently achieved efficiencies as high as 40.7%. (see, Martin and Green, Progress in Photovoltaics: Research and Applications 2006, 14, 455) Combined with advanced concentrator technologies that allow high illumination intensities, these cells are expected by many to become the most cost effective solution for terrestrial applications. Such a breakthrough would open up an enormous market for this technology, which so far has been limited to niche applications such as power production in space. The most efficient multijunction designs are based on lattice-matched GaInP/GaInAs/Ge combinations with 1.8 eV, 1.4 eV and 0.67 eV band gaps, respectively. These systems suffer from two basic limitations: the high cost of the Ge-substrates on which they are fabricated and excess photogenerated current in the Ge subcell.

Current Ge/InGaAs/InGaP cells are grown on bulk Ge substrates, which represent approximately ⅓ of their cost. (see, Sherif and King, National Center for Photovoltaics Program Review Meeting, 2001, p. 261). The Ge-current can be reduced by lowering the band gap of the middle cell, but this requires a higher In concentration that introduces a severe lattice mismatch. Alternatively, Ge may be replaced with a higher band gap semiconductor or to introduce an additional subcell based on this new material. So far the main candidate for this additional junction has been InGaAsN, but this system has severe materials problems that have not been overcome to date.

This problem has been somewhat mitigated by using ultrathin Ge buffer layers, but this implies that a Ge cell is not included. For example, III-V solar cells have been demonstrated on Si substrates using ultrathin Ge buffer layers or thick compositionally graded Ge₁₋ₓSiₓ alloys as templates. (see, Sherif and King, supra; Ringel et al., in 12th European PVSCE, Glasgow, Scottland, 2000; Zahler et al., Mat. Res. Soc. Symp. Proc. 2001, 681E, I.4.5.1; and Ginige, et al. Semicond. Sci. Technol. 2006, 21, 775). However, in all of these cases, however, the Ge materials were not active components of the multijunction cell. The decision not to incorporate a Ge-cell in these structures is partly due to the high density of dislocations (>10⁶ cm⁻²) found in Ge on Si buffers. An additional problem in these structures is the generation of wafer bowing due to the large thermal expansion mismatch between Ge and Si. It is well known that the efficiency of the three junction Ge/InGaAs/InGaP cell could be increased by incorporating a fourth junction between the Ge cell and the InGaAs cell. (see, Senft, J. Elec. Mat. 2005, 34, 1099; and Dimroth and Kurtz, MRS Bull. 2007, 32, 230). The material in this fourth cell should be lattice matched to Ge and have a band gap close to 1 eV. Unfortunately, up to now there were no suitable materials available possessing this property, with the possible exception of GaAsN alloys, which due to a “giant bowing” effect can have a band gap below that of GaAs (see, Wei and Zunger, Phys. Rev. Lett. 1996, 76, 664). However, attempts to incorporate these alloys as a fourth junction have not been very successful due to material quality problems

Therefore, there exists a need in the art to address the preceding problems in solar cells utilizing Ge layers.

### SUMMARY OF THE INVENTION

The present disclosure is based on growth of device-quality Ge, Ge₁₋ₓSnₓ, and Ge_{1-x-y}SiₓSn_{y} alloys on Si substrates. The photovoltaic potential of these materials arises from the low cost of the Si substrates and from the ability of Sn-containing materials to absorb solar infrared radiation and act as templates for subsequent growth over a wide range of lattice constants. Specifically, herein we have developed materials that bring about dramatic reductions in cost and increased efficiencies in hybrid group IV/III-V solar cells and in crystalline Si solar cells.

In one aspect, the invention provides semiconductor structures comprising (i) a Si substrate; (ii) a buffer region formed directly over the Si substrate, wherein the buffer region comprises (a) a Ge layer having a threading dislocation density below about 10⁵/cm², wherein the Ge layer is formed directly over the Si substrate; or (b) a Ge₁₋ₓSnₓ layer formed directly over the Si substrate and a Ge_{1-x-y}SiₓSn_{y} layer formed over the Ge₁₋ₓSnₓ layer; and (iii) a plurality of III-V active blocks formed over the buffer region.

In a second aspect, the invention provides method for forming a semiconductor structure comprising forming a buffer region directly over a Si substrate; and forming a plurality of III-V active blocks over the buffer region, wherein the buffer region comprises (a) a Ge layer having a threading dislocation density below 10⁵/cm² and a Ge_{1-x-y}SiₓSn_{y} layer formed over the Ge layer, wherein the Ge layer is formed directly over the Si substrate; or (b) a Ge₁₋ₓSnₓ layer and a Ge_{1-x-y}SiₓSn_{y} layer formed over the Ge₁₋ₓSnₓ layer, wherein the Ge₁₋ₓSnₓ layer is formed directly over the Si substrate.

In a third aspect, the invention provides Ge_{1-x-y}SiₓSn_{y} alloys that are lattice matched or pseudomorphically strained to Ge, wherein x is about 0.07 to about 0.42 and y is about 0.01 to about 0.20.

In a fourth aspect, the invention provides Ge_{1-x-y}SiₓSn_{y} alloys, lattice matched or pseudomorphically strained to Ge, having a bandgap of about 0.80 eV to about 1.40 eV.

In a fifth aspect, the invention provides a GeSiSn alloy of the formula, Ge_{1-X}(Si_{β}Sn_{1-β)X} wherein β is about 0.79 and X is a value greater than 0 and less than 1.

### BRIEF DESCRIPTION OF THE DRAWINGS

FIG. 1 shows a band lineup at a lattice-matched Ge_{1-x-y}SiₓSn_{y}/Ge interface. The subscripts cΓ, cΓ and cX refer to the conduction band minima at the corresponding points in the Brillouin zone of the diamond structure; the subscript νΓ indicates the valence band maximum at the Γ point of the Brillouin zone; the values highlight the smallest energy gaps in the two materials, and the discontinuities indicate the conduction and valence band offsets.

FIG. 2 shows XTEMs of a Ge films grown on Si(100) at 360° C.; (a) Phase contrast micrograph showing a 2.5 μm film thickness with a flat surface; (b) diffraction contrast micrograph of a 0.8 μm film showing an atomically smooth surface and absence of penetrating defects; and (c) high-resolution image of the heteroepitaxial interface showing the location of Lomer defects providing strain relief.

FIG. 3 shows the absorption coefficient of Ge₁₋ₓSnₓ as a function of incident light energy; enhanced absorption above 0.4 eV suggests applications of these materials as photovoltaic components. Inset: absorption coefficients of Ge_{0.98}Sn_{0.02} and pure Ge showing a tenfold increase of absorption at 1.55 μm.

FIG. 4 shows (top) Diffraction contrast XTEM micrograph showing 3 nm thick Ge_{0.98}Sn_{0.02} quantum wells sandwiched by higher-gap Ge_{1-x-y}SiₓSn_{y} barriers. (inset) PL signal from such as structure. (bottom) Z-contrast images of a single quantum well (light contrast).

FIG. 5 shows Top: XTEM, Z-contrast micrograph of a Ge_{0.64}Si_{0.32}Sn_{0.04} epilayer (light contrast) grown on a Ge_{0.97}Sn_{0.03} buffer. The film surface is flat and the both layers are highly uniform and perfectly coherent. Bottom: Families of band gaps for the same value of the lattice constant in ternary Ge_{1-x-y}SiₓSn_{y} alloys.

FIG. 6 shows (Inset) XRD <224> reciprocal space maps of Ge_{0.98}Sn_{0.02}/Ge_{0.60}Si_{0.30}Sn_{0.10} as grown. The Ge_{0.98}Sn_{0.02} and Ge_{0.60}Si_{0.30}Sn_{0.10} peaks overlap indicating perfect lattice matching. The relaxation line passes through the center of the peak common to both materials indicating full relaxation in the as grown material. The main panel shows the XRD <224> reciprocal space maps of the Ge/Ge_{0.98}Sn_{0.02}/Ge_{0.60}Si_{0.03}Sn_{0.10} stack. The Ge epilayer is coherent with the buffer and fully relaxed as evidenced by the relaxation line passing through the center of the Ge peak. The Ge_{0.98}Sn_{0.02}/Ge_{0.60}Si_{0.30}Sn_{0.10} is compressively strained (peak fall below relaxation line).

FIG. 7 shows (a) photoluminescence spectrum (PL) of In_{0.03}Ga_{0.97}As/Ge_{0.98}Sn_{0.02}/Si. (b) Interface XTEM image of a lattice matched GaAsSb/Ge₁₋ₓSnₓ showing perfect epitaxy. (c) Structure of GaAs/Ge₁₋ₓSn, interface indicating the energetically favorable location of Sn is deep within the Ge₁₋ₓSnₓ buffer. (d) plot of the lattice constant vs. direct gaps in III-V (dashed) and IV-IV (solid line) semiconductors. Gray area indicates the compositions of synthesized ternary alloys lattice matching to the Ge_{1-y}Sn_{y} (y<0.08). Relaxed In_{0.4}Ga_{0.6}As and GaAs_{0.6}Sb_{0.4} grown epitaxially on Ge_{0.92}Sn_{0.08}. (e) Micrograph of a typical lattice-matched Ge₁₋ₓSnₓ/GaAsSb interface devoid of threading defects.

FIG. 8 shows (a, Top) a bright field XTEM micrograph of the entire Ge/Ge_{0.74}Si_{0.20}Sn_{0.055} film thickness grown directly on Si (100). The arrow in the image indicates the interface between the layers in the heterostructure; and (b, Bottom) a high resolution image of the interface showing complete commensuration between the cubic buffer and the epilayer.

FIG. 9 shows a 128-atom (64×2) representation of the Ge_{0.76}Si_{0.19}Sn_{0.05}/Ge interface obtained from DFT-based first principles structure optimization showing that the lattice matching of this composition with the underlying Ge is readily achievable.

FIG. 10 shows a (Top) Bright field micrograph of a Ge/Ge_{0.90}Si_{0.80}Sn_{0.02} film. (Bottom) SAED pattern in (110) projection (left) and high resolution image of the interface (right).

FIG. 11 shows the absorption coefficient α as well as the position of the direct band edge (vertical lines) for families of Ge_{1-x-y}SiₓSn_{y} alloys deposited on Ge-buffered Si.

FIG. 12 shows (a) a HR-XRD reciprocal space maps (RSM) of the (224) reflections for a Si(100)/Ge/Ge_{0.90}Si_{0.08}Sn_{0.02} sample showing the temperature dependence of the heterostructure upon heating to 700° C. and quenching to ambient. (b) and (c) In plane and perpendicular (respectively) lattice expansion plots for the Si(100)/Ge/Ge_{0.90}Si_{0.85}Sn_{0.02} sample, corresponding Ge/Si(100) template, and the Si(100) substrate.

FIG. 13 shows (a) the imaginary part of the dielectric function of selected GeSiSn samples in the spectral region corresponding to the direct gap E₀; the dotted lines indicate the values obtained from the room-temperature spectroscopic ellipsometry data. The solid lines show fits with theoretical expressions including excitonic effects and broadening, as discussed in the text; and (b) a typical low-temperature photoreflectance spectrum used to confirm the direct-gap values obtained from the ellipsometry study; the dotted line corresponds to the experimental data and the solid line is a fit using a three-dimensional critical point minimum and a Lorentzian excitonic contribution with a fixed binding energy of 4.6 meV.

FIG. 14 shows the direct-gap values in GeSiSn alloys lattice-matched to Ge as a function of the combined Si+Sn fraction X. The markers correspond to the experimental values. The dashed line indicates a linear interpolation between Si, Ge, and a-Sn.; the dotted line shows the linear term in the quadratic expression for the band-gap energy [Eq. (1)] as predicted from experiments on GeSn and SiGe alloys; the solid line is a fit with Eq. (1) using the linear and quadratic coefficients as adjustable parameters.

FIG. 15 shows an HR—XRD reciprocal space maps (left) and corresponding 0-20 plots (right) of Ge/SiGeSn/GaAs and Ge/SiGeSn/InGaAs samples grown on Si(100). Panel (a) clearly shows two distinct spots in the (224) RSM associated with the lattice mismatch between the coupled Ge/GeSiSn layers and slightly mismatched GaAs overlayer; the corresponding (224) RSM for the Ge/GeSiSn/InGaAs sample (Panel (b)) shows only a single spot, indicating perfect lattice matching between the Ge/GeSiSn and InGaAs layers.

FIG. 16 shows a diffraction contrast XTEM micrograph showing growth of InGaAs on Si (100) via a lattice matched Ge/Si_{0.08}Ge_{0.90}Sn_{0.02} template. Inset is a SAED pattern of the heterostructure in <100> projection showing an overlap of the diffraction spots consistent with the close matching of the lattice dimensions.

FIG. 17 shows a Ge on Si film with a thickness of 5 μm and a flat surface (top); the inset shows fraction of the solar spectrum captured by Ge (upper line) and corresponding GaAs-filtered solar spectrum captured by Ge (lower line), reflection effects are ignored; bottom left shows the (224) reciprocal space indicating a fully relaxed Ge/Si(100) heterostructure; bottom right shows an AFM image of the Ge surface showing atomic step heights.

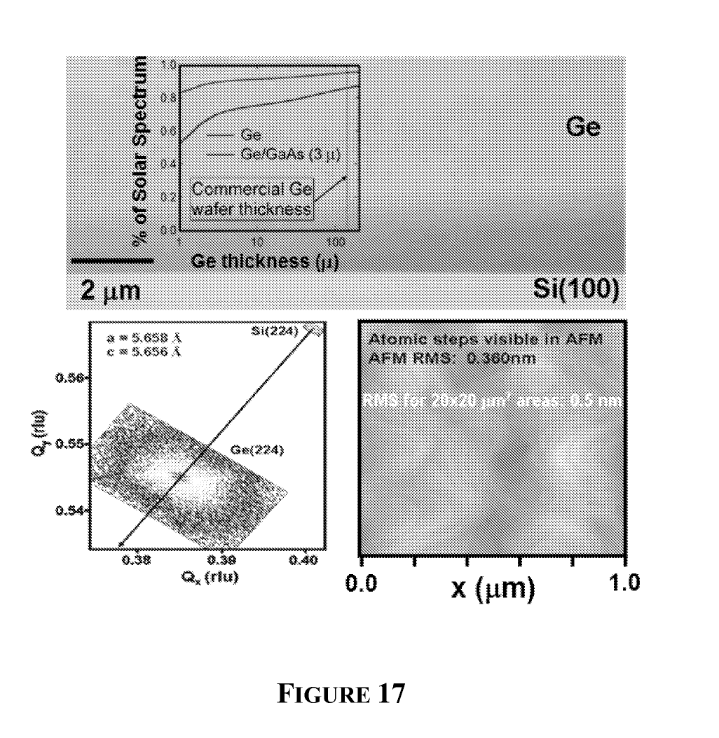

FIG. 18 shows a SIMS profile of a p-i Ge structure showing a chemically abrupt transition between the layers; the B content is 1.5×10¹⁸ atoms per cm³.

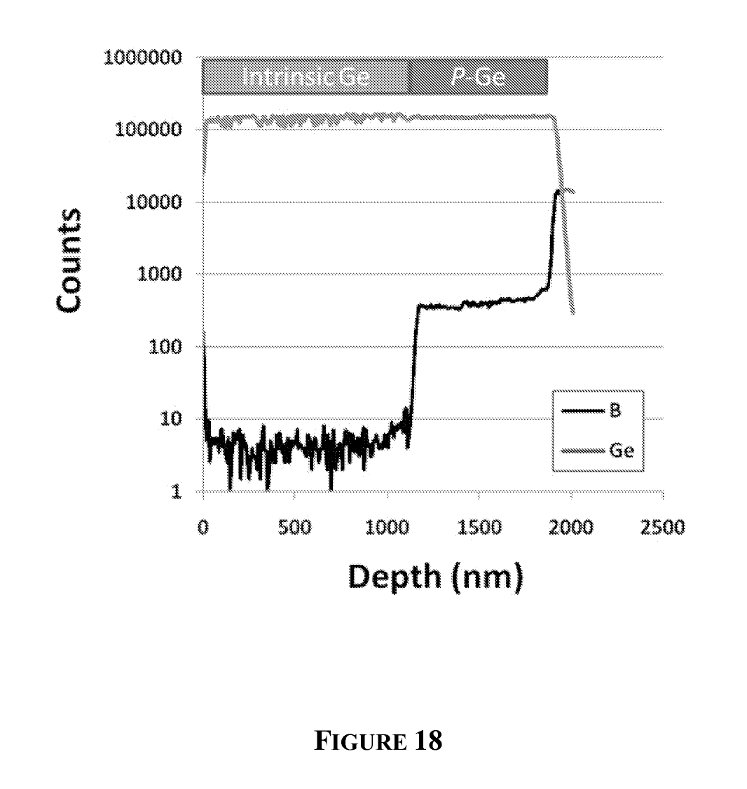

### DETAILED DESCRIPTION OF THE INVENTION

Herein, the invention generally provides semiconductor structures built on Si substrates via Ge or Ge₁₋ₓSnₓ/Ge_{1-x-y}SiₓSn_{y} buffer overlayers. In particular, the present Ge overlayers can act as active components within the semiconductor structure. The cost savings utilizing the structures provided herein can be substantial; not only because Si wafers are far cheaper, but also because they are less brittle and available in larger sizes. The superior mechanical properties make it possible to fabricate devices on substrates thinner than, for example, 100 μm. For terrestrial applications using solar concentrators, the larger size of the Si wafers (e.g., 3 in., 4 in., 5 in., 6 in., 8 in., 10 in., or 12 in. diameter Si wafers) can accommodate the same number of solar cells with larger individual dimensions. This imposes less severe constraints on the concentrator optical design, thereby lowering its cost. Finally, cells fabricated on Si substrates are lighter than those fabricated on bulk Ge wafers, which is an important consideration for space applications.

### DEFINITIONS

It should be understood that when a layer is referred to as being “on” or “over” another layer or substrate, it can be directly on the layer or substrate, or an intervening layer may also be present. It should also be understood that when a layer is referred to as being “on” or “over” another layer or substrate, it may cover the entire layer or substrate, or a portion of the layer or substrate.

It should be further understood that when a layer is referred to as being “directly on” or “directly over” another layer or substrate, the two layers are in direct contact with one another with no intervening layer. It should also be understood that when a layer is referred to as being “directly on” or “directly over” another layer or substrate, it may cover the entire layer or substrate, or a portion of the layer or substrate.

The terms “region” and “block” as used herein, mean a single-layer or a multi-layer structure.

The term “active block” as used herein, means an active single layer or multilayer, such as a heterostructure, p-n junction, p-i-n junction, or single quantum well (QW) or multiple QW that can provide a photocurrent under optical illumination.

The term “III-V semiconductor” as used herein means a material where the constituent elements are selected from Groups IIIA and VA of the periodic table, wherein at least one constituent element is selected from Group IIIA of the periodic table and at least one constituent element is selected from Group VA of the periodic table. Examples of III-V semiconductors include, but are not limited to (a) binaries such as, but not limited to, Aluminum antimonide (AlSb), Aluminum arsenide (AlAs), Aluminum nitride (AlN), Aluminum phosphide (AlP), Boron nitride (BN), Boron phosphide (BP), Boron arsenide (BAs), Gallium antimonide (GaSb), Gallium arsenide (GaAs), Gallium nitride (GaN), Gallium phosphide (GaP), Indium antimonide (InSb), Indium arsenide (InAs), Indium nitride (InN), and Indium phosphide (InP); (b) ternaries such as, but not limited to, Aluminum gallium arsenide (AlGaAs, AlₓGa₁₋ₓAs), Indium gallium arsenide (InGaAs, InₓGa₁₋ₓAs), Aluminum indium arsenide (AlInAs), Aluminum indium antimonide (AlInSb), Gallium arsenide nitride (GaAsN), Gallium arsenide phosphide (GaAsP), Aluminum gallium nitride (AlGaN), Aluminum gallium phosphide (AlGaP), Indium gallium nitride (InGaN), Indium arsenide antimonide (InAsSb), and Indium gallium antimonide (InGaSb); (c) quaternaries such as, but not limited to, Aluminum gallium indium phosphide (AlGaInP, also InAlGaP, InGaAlP, AlInGaP), Aluminum gallium arsenide phosphide (AlGaAsP), Indium gallium arsenide phosphide (InGaAsP), Aluminum indium arsenide phosphide (AlInAsP), Aluminum gallium arsenide nitride (AlGaAsN), Indium gallium arsenide nitride (InGaAsN), and Indium aluminum arsenide nitride (InAIAsN); and (d) quinaries such as, but not limited to, Gallium indium nitride arsenide antimonide (GaInNAsSb). Higher order III-V semiconductors include, for example, Indium gallium aluminum arsenide antimonide phosphide InGaAlAsSbP.

The term “III-V active block” as used herein, means an active block, as defined herein, comprising at least one layer of an III-V semiconductor, as defined herein.

The term “lattice matched” as used herein means that the two referenced materials have the same or lattice constants differing by up to +/−0.2%. For example, GaAs and AlAs are lattice matched, having lattice constants differing by ˜0.12%.

The term “pseudomorphically strained” as used herein means that layers made of different materials with a lattice parameter difference up to +/−2% that can be grown on top of other lattice matched or strained layers without generating misfit dislocations. In certain embodiments, the lattice parameters differ by up to +/−1%. In other certain embodiments, the lattice parameters differ by up to +/−0.5%. In further certain embodiments, the lattice parameters differ by up to +/−0.2%.

The term “bandgap” or “direct band edge” as used herein means the energy difference between the highest occupied state of the valence band and the lowest unoccupied state of the conduction band of the material. The bandgap for a p-n junction, as used herein, refers to the bandgap of the material that forms the p-n junction.

The term “layer” as used herein, means a continuous region of a material, typically grown on a substrate, (e.g., an III-V semiconductor) that can be uniformly or non-uniformly doped and that can have a uniform or a non-uniform composition across the region.

The term “tunnel junction” as used herein, means a region comprising two heavily doped layers with n and p, respectively. Both of these layers can be of the same materials (homojunction) or different materials (heterojunction).

The term “p-n junction” as used herein, means a region comprising at least two layers of similar or dissimilar materials doped n and p type, respectively.

The term “p-i-n junction” as used herein, means a region comprising at least two layers of a material doped n and p type, respectively, and wherein the n-doped and p-doped layers are separated by an intrinsic semiconductor layer.

The term “p-doped” as used herein means atoms have been added to the material to increase the number of free positive charge carriers.

The term “n-doped” as used herein means atoms have been added to the material to increase the number of free negative charge carriers.

The term “intrinsic semiconductor” as used herein means a semiconductor material in which the concentration of charge carriers is characteristic of the material itself rather than the content of impurities (or dopants).

The term “compensated semiconductor” refers to a semiconductor material in which one type of impurity (or imperfection, for example, a donor atom) partially (or completely) cancels the electrical effects on the other type of impurity (or imperfection, for example, an acceptor atom).

In a first aspect, the invention provides, semiconductor structures comprising (i) a Si substrate; (ii) a buffer region formed directly over the Si substrate, wherein the buffer region comprises (a) a Ge layer having a threading dislocation density below about 10⁵/cm², wherein the Ge layer is formed directly over the Si substrate; or (b) a Ge₁₋ₓSnₓ layer formed directly over the Si substrate and a Ge_{1-x-y}SiₓSn_{y} layer formed over the Ge₁₋ₓSnₓ layer; and (iii) a plurality of III-V active blocks formed over the buffer region.

In one preferred embodiment, the buffer region comprises a Ge layer having a threading dislocation density below about 10⁵ cm⁻². In another preferred embodiment, the buffer region comprises a Ge layer having a threading dislocation density below about 10⁵ cm⁻²; and a Ge_{1-x-y}SiₓSn_{y} layer formed over the Ge layer, wherein the Ge_{1-x-y}SiₓSn_{y} layer is lattice matched or pseudomorphically strained to the Ge layer.

In a preferred embodiment of any of the preceding embodiments, the buffer region may comprise at least one active block. In certain preferred embodiments, the buffer region comprises a first active block comprising the Ge layer having a threading dislocation density below 10⁵ cm². In other preferred embodiments, the buffer region comprises (i) a first active block comprising the Ge layer having a threading dislocation density below 10⁵ cm⁻² and (ii) a second active block comprising a Ge_{1-x-y}SiₓSn_{y} layer, wherein the second active block is formed over (e.g., directly on) the first active block.

In a preferred embodiment of any of the preceding embodiments, the first active block can comprise a p-n junction or p-i-n junction comprising the Ge layer. In one preferred embodiment, the first active block can comprise a p-n junction, wherein each layer of the p-n junction comprises a p-doped and n-doped Ge layer having a threading dislocation density below 10⁵ cm⁻², respectively. In another preferred embodiment, the first active block can comprise a p-i-n junction, wherein each layer of the p-i-n junction comprises, respectively, a p-doped, intrinsic, and n-doped Ge layer having a threading dislocation density below 10⁵ cm⁻².

In a preferred embodiment of any of the preceding embodiments, the second active block can comprise a p-n junction or p-i-n junction comprising the Ge_{1-x-y}SiₓSn_{y} layer. In one preferred embodiment, the second active block can comprise a p-n junction, wherein each layer of the p-n junction comprises a p-doped and n-doped Ge_{1-x-y}SiₓSn_{y} layer, respectively. In another preferred embodiment, the second active block can comprise a p-i-n junction, wherein each layer of the p-i-n junction comprises, respectively, a p-doped, intrinsic, and n-doped Ge_{1-x-y}SiₓSn_{y} layer.

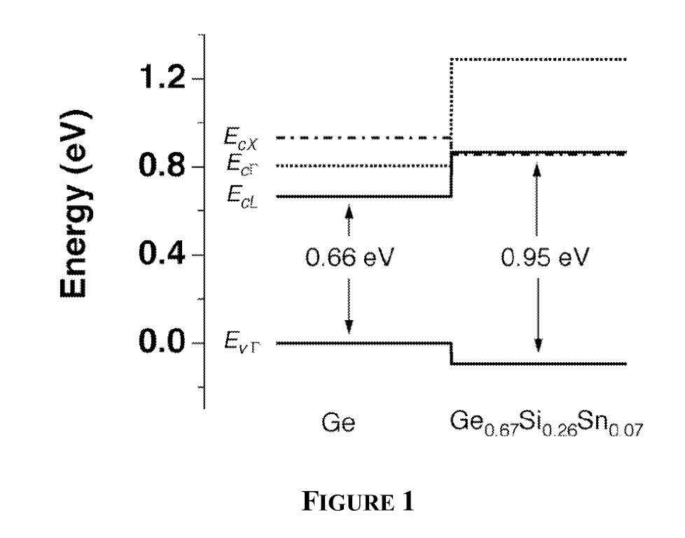

The Ge_{1-x-y}SiₓSn_{y} layers in the preceding embodiments can be lattice matched or pseudomorphically strained to the Ge layer. The band lineup for an example of such a lattice matched Ge_{1-x-y}SiₓSn_{y} layer is illustrated in FIG. 1. This was calculated using the measured compositional dependence of the alloy band structure and standard deformation potential theory (see, Menendez and Kouvetakis, Appl. Phys. Lett. 2004, 85, 1175). The ternary Ge_{1-x-y}SiₓSn_{y} alloy of FIG. 1 has a bandgap of 0.95 eV. Notice that the L and X minima are nearly degenerate, which should increase the indirect gap absorption. The corresponding direct gap is at 1.38 eV, but it is also possible to lower it to 1.0 eV while preserving a lattice constant matched to that of Ge.

Ternary Ge_{1-x-y}SiₓSn_{y} alloys have lattice constants and band gaps which can be adjusted independently and over a wide range. For example, the Ge_{1-x-y}SiₓSn_{y} layers in the preceding embodiments can comprise a Ge_{1-x-y}SiₓSn_{y} alloy where y is about 0.01 to about 0.20, and wherein the Ge_{1-x-y}SiₓSn_{y} alloy is lattice matched or pseudomorphically strained to Ge.

In another preferred embodiment, the Ge_{1-x-y}SiₓSn_{y} layers can comprise a Ge_{1-x-y}SiₓSn_{y} alloy wherein the Ge_{1-x-y}SiₓSn_{y} layer is lattice matched or pseudomorphically strained to the Ge layer, and wherein x is about 0.07 to about 0.42. In another preferred embodiment, the Ge_{1-x-y}SiₓSn_{y} layers can comprise a Ge_{1-x-y}SiₓSn_{y} alloy wherein the Ge_{1-x-y}SiₓSn_{y} layer is lattice matched or pseudomorphically strained to the Ge layer, and wherein x is about 0.07 to about 0.42 and y is about 0.01 to about 0.20. In another preferred embodiment, the Ge_{1-x-y}SiₓSn_{y} layers can comprise a Ge_{1-x-y}SiₓSn_{y} alloy wherein the Ge_{1-x-y}SiₓSn_{y} layer is lattice matched or pseudomorphically strained to the Ge layer, and wherein x is about 0.19 to about 0.37 and y is about 0.01 to about 0.20. In another preferred embodiment of the preceding, y can be about 0.02 to about 0.12 or about 0.05 to about 0.09

In another preferred embodiment, the Ge_{1-x-y}SiₓSn_{y} layers can comprise a Ge_{1-x-y}SiₓSn_{y} alloy wherein the Ge_{1-x-y}SiₓSn_{y} layer is lattice matched or pseudomorphically strained to the Ge layer, and wherein x is about 0.05 to about 0.20. In another preferred embodiment, the Ge_{1-x-y}SiₓSn_{y} layers can comprise a Ge_{1-x-y}SiₓSn_{y} alloy wherein the Ge_{1-x-y}SiₓSn_{y} layer is lattice matched or pseudomorphically strained to the Ge layer, and wherein x is about 0.05 to about 0.20 and y is about 0.01 to about 0.20. In another preferred embodiments of the preceding, y can be about 0.02 to about 0.12 or about 0.05 to about 0.09. In one preferred embodiment, the Ge_{1-x-y}SiₓSn_{y} layers can have a bandgap of about 0.80 eV to about 1.40 eV, wherein the Ge_{1-x-y}SiₓSn_{y} layers are lattice matched or pseudomorphically strained to the Ge layer. In another preferred embodiment, the Ge_{1-x-y}SiₓSn_{y} layers can have a bandgap of about 0.90 eV to about 1.35 eV, wherein the Ge_{1-x-y}SiₓSn_{y} layers are lattice matched or pseudomorphically strained to the Ge layer. In another preferred embodiment, the Ge_{1-x-y}SiₓSn_{y} layers can have a bandgap of about 0.95 eV to about 1.20 eV, wherein the Ge_{1-x-y}SiₓSn_{y} layers are lattice matched or pseudomorphically strained to the Ge layer.

In another preferred embodiment, the Ge_{1-x-y}SiₓSn_{y} layers can comprise, for example, an alloy of Ge₁₋ₓ(Si_{β}Sn_{1-β})_{X} where β is about 0.79 and X is a value greater than 0 and less than 1. For example, X can be between about 0.05 and about 0.95; or between about 0.05 and about 0.90; or between about 0.05 and about 0.85; or between about 0.05 and about 0.80; or between about 0.05 and about 0.75; or between about 0.05 and about 0.70; or between about 0.05 and about 0.65; or between about 0.05 and about 0.60; or between about 0.05 and about 0.55; or between about 0.05 and about 0.50.

For example, such alloys include, but are not limited to,

| X | alloy |
|---|---|
| 0.05 | Ge_{0.95}Si_{0.0395}Sn_{0.0105} |
| 0.10 | Ge_{0.90}Si_{0.079}Sn_{0.021} |
| 0.15 | Ge_{0.85}Si_{0.1185}Sn_{0.0315} |
| 0.20 | Ge_{0.80}Si_{0.158}Sn_{0.042} |
| 0.25 | Ge_{0.75}Si_{0.1975}Sn_{0.0525} |
| 0.30 | Ge_{0.70}Si_{0.237}Sn_{0.063} |
| 0.35 | Ge_{0.65}Si_{0.2765}Sn_{0.0735} |
| 0.40 | Ge_{0.60}Si_{0.316}Sn_{0.084} |
| 0.45 | Ge_{0.55}Si_{0.3555}Sn_{0.0945} |
| 0.50 | Ge_{0.50}Si_{0.395}Sn_{0.105} |
| 0.55 | Ge_{0.45}Si_{0.4345}Sn_{0.1155} |
| 0.60 | Ge_{0.40}Si_{0.474}Sn_{0.126} |
| 0.65 | Ge_{0.35}Si_{0.5135}Sn_{0.1365} |

In another preferred embodiment, the Ge_{1-x-y}SiₓSn_{y} layers can comprise, for example, Si_{0.75}Ge_{0.905}Sn_{0.02}, Si_{0.08}Ge_{0.90}Sn_{0.02}, Si_{0.19}Ge_{0.76}Sn_{0.05}, Si_{0.20}Ge_{0.745}Sn_{0.055}, Si_{0.23}Ge_{0.71}Sn_{0.06}, Si_{0.26}Ge_{0.67}Sn_{0.07}, Si_{0.30}Ge_{0.60}Sn_{0.10}, Si_{0.31}Ge_{0.60}Sn_{0.09}, Si_{0.32}Ge_{0.64}Sn_{0.04}, or Si_{0.41}Ge_{0.48}Sn_{0.11}, Si_{0.27}Ge_{0.56}Sn_{0.17}, each lattice matched or pseudomorphically strained to the Ge layer.

In another preferred embodiment, the Ge_{1-x-y}SiₓSn_{y} layers can comprise, for example, Si_{0.075}Ge_{0.905}Sn_{0.02}, Si_{0.08}Ge_{0.90}Sn_{0.02}, Si_{0.19}Ge_{0.76}Sn_{0.05}, or Si_{0.20}Ge_{0.745}Sn_{0.055}, each lattice matched or pseudomorphically strained to the Ge layer.

In another preferred embodiment, a Ge_{1-x-y}SiₓSn_{y} layer, lattice matched or pseudomorphically strained to a Ge layer, can have x and y for the Ge_{1-x-y}SiₓSn_{y} layer in a ratio of about 3:1 to about 5:1. In certain other preferred embodiments, a Ge_{1-x-y}SiₓSn_{y} layer, lattice matched or pseudomorphically strained to a Ge layer, can have x and y for the Ge_{1-x-y}SiₓSn_{y} layer in a ratio of about 3.75:1 to about 4.75:1. In certain other preferred embodiments, a Ge_{1-x-y}SiₓSn_{y} layer, lattice matched or pseudomorphically strained to a Ge layer can have x and y for the Ge_{1-x-y}SiₓSn_{y} layer in a ratio of about 3.5:1 to about 4.5:1. In certain other preferred embodiments, a Ge_{1-x-y}SiₓSn_{y} layer, lattice matched or pseudomorphically strained to a Ge layer, can have x and y for the Ge_{1-x-y}SiₓSn_{y} layer in a ratio of about 3.25:1 to about 4.25:1. In certain other preferred embodiments, a Ge_{1-x-y} SiₓSn_{y} layer, lattice matched or pseudomorphically strained to a Ge layer, can have x and y for the Ge_{1-x-y}SiₓSn_{y} layer in a ratio of about 3.10:1 to about 4.10:1. In certain other preferred embodiments, a Ge_{1-x-y}SiₓSn_{y} layer, lattice matched or pseudomorphically strained to a Ge layer, can have x and y for the Ge_{1-x-y}SiₓSn_{y} layer in a ratio of about 4:1.

In a preferred embodiment of any of the preceding embodiments, the Ge layer having a threading dislocation density below 10⁵ cm⁻² and/or the first active block can have a thickness of about 0.1 μm to about 5 μm. For example, the Ge layer and/or the first active block can have a thickness of about 0.1 μm to about 4.0 μm; about 0.1 μm to about 3.0 μm; about 0.1 μm to about 2.0 μm; 0.1 μm to about 1.0 μm; or 0.1 μm to about 0.75 μm; or about 0.1 μm to about 0.50 μm; or about 0.2 μm to about 0.50 μm. In one preferred embodiment, the Ge layer and/or the first active block can have a thickness of about 0.1 μm to about 1.0 μm.

Alternatively, in a preferred embodiment of any of the preceding embodiments, the Ge layer having a threading dislocation density below 10⁵ cm⁻² and/or the first active block can have a thickness of greater than about 5 μm. For example, the Ge layer and/or the first active block can have a thickness of about 5 μm to about 100 μm; or about 5 μm to about 50 μm; or about 5 μm to about 25 μm. In one preferred embodiment, the Ge layer and/or the first active block can have a thickness of about 5 μm to about 10 μm.

In a preferred embodiment of any of the preceding embodiments, the Ge_{1-x-y}SiₓSn_{y} layer and/or the second active block can have a thickness of about 0.05 to about 5 μm. For example, the Ge_{1-x-y}SiₓSn_{y} layer and/or the second active block can have a thickness of about 0.05 μm to about 4.0 μm; about 0.05 μm to about 3.0 μm; about 0.05 μm to about 2.0 μm; 0.05 μm to about 1.0 μm; or 0.05 μm to about 0.75 μm; or about 0.05 μm to about 0.50 μm; or about 0.05 μm to about 0.25 μm. In one preferred embodiment, the Ge_{1-x-y}SiₓSn_{y} layer and/or the second active block can have a thickness of about 0.05 μm to about 1.0 μm.

Alternatively, in a preferred embodiment of any of the preceding embodiments, the Ge_{1-x-y}SiₓSn_{y} layer and/or the second active block can have a thickness of greater than about 5 μm. For example, the Ge_{1-x-y}SiₓSn_{y} layer and/or the second active block can have a thickness of about 5 μm to about 100 μm; or about 5 μm to about 50 μm; or about 5 μm to about 25 μm. In one preferred embodiment, the Ge_{1-x-y}SiₓSn_{y} layer and/or the second active block can have a thickness of about 5 μm to about 10 μm.

In a preferred embodiment of any of the preceding embodiments, the buffer region can have a thickness of about 0.05 μm to about 5 μm. For example, the buffer region can have a thickness of about 0.05 μm to about 4.0 μm; about 0.05 μm to about 3.0 μm; about 0.05 μm to about 2.0 μm; about 0.05 μm to about 1.0 μm; or about 0.05 μm to about 0.75 μm; or about 0.05 μm to about 0.50 μm; or about 0.05 μm to about 0.25 μm. In one preferred embodiment, the buffer region can have a thickness of about 0.05 μm to about 1.0 μm.

Alternatively, in a preferred embodiment of any of the preceding embodiments, the buffer region can have a buffer thickness greater than about 5 μm. For example, the buffer thickness can be about 5 μm to about 100 μm; or about 5 μm to about 50 μm; or about 5 μm to about 25 μm.

In another preferred embodiment, the buffer region comprises a Ge₁₋ₓSnₓ layer formed directly over the Si substrate and a Ge_{1-x-y}SiₓSn_{y} layer formed over (e.g., directly over) the Ge₁₋ₓSnₓ layer. In certain preferred embodiments, the buffer region comprises a first active block comprising the Ge₁₋ₓSnₓ layer formed directly over the Si substrate. In another preferred embodiment, the buffer region can comprise a first active block comprising the Ge₁₋ₓSnₓ layer formed directly over the Si substrate and a second active block comprising the Ge_{1-x-y}SiₓSn_{y} layer, wherein the second active block is formed over the first active block.

In a preferred embodiment of any of the preceding embodiments, the first active block can comprise a p-n junction or p-i-n junction comprising the Ge₁₋ₓSnₓ layer. In one preferred embodiment, the first active block can comprise a p-n junction, wherein each layer of the p-n junction comprises a p-doped and n-doped Ge₁₋ₓSnₓ layer, respectively. In another preferred embodiment, the first active block can comprise a p-i-n junction, wherein each layer of the p-i-n junction comprises, respectively, a p-doped, intrinsic, and n-doped Ge₁₋ₓSnₓ layer.

Further, in a preferred embodiment of any of the preceding embodiments, the second active block can comprise a p-n junction or p-i-n junction comprising the Ge_{1-x-y}SiₓSn_{y} layer. In one preferred embodiment, the second active block can comprise a p-n junction, wherein each layer of the p-n junction comprises a p-doped and n-doped Ge_{1-x-y}SiₓSn_{y} layer, respectively. In another preferred embodiment, the second active block can comprise a p-i-n junction, wherein each layer of the p-i-n junction comprises, respectively, a p-doped, intrinsic, and n-doped Ge_{1-x-y}SiₓSn_{y} layer.

In another preferred embodiment, the buffer region can comprise the Ge₁₋ₓSnₓ layer formed directly over the Si substrate and a first active block comprising the Ge_{1-x-y}SiₓSn_{y} layer, wherein the first active block is formed over the Ge₁₋ₓSnₓ layer. In one preferred embodiment, the first active block can comprise a p-n junction, wherein each layer of the p-n junction comprises a p-doped and n-doped Ge_{1-x-y}SiₓSn_{y} layer, respectively. In another preferred embodiment, the first active block can comprise a p-i-n junction, wherein each layer of the p-i-n junction comprises, respectively, a p-doped, intrinsic, and n-doped Ge_{1-x-y}SiₓSn_{y} layer.

The Ge₁₋ₓSnₓ layers in the preceding embodiments can comprise, for example, a Ge₁₋ₓSnₓ alloy, wherein x is about 0.01 to about 0.20 (e.g., Ge_{0.98}Sn_{0.02} or Ge_{0.91}Sn_{0.09}). For example, the Ge₁₋ₓSnₓ layers in the preceding embodiments can comprise, a Ge₁₋ₓSnₓ alloy, wherein x is about 0.02 to about 0.10.

Further, in a preferred embodiment of any of the preceding embodiments, the Ge₁₋ₓSnₓ layers can have a thickness of about 0.1 μm to about 5 μm. For example, the Ge₁₋ₓSnₓ layer can have a thickness of about 0.1 μm to about 4.0 μm; about 0.1 μm to about 3.0 μm; about 0.1 μm to about 2.0 μm; 0.1 μm to about 1.0 μm; or about 0.1 μm to about 0.75 μm; or about 0.1 μm to about 0.50 μm; or about 0.2 μm to about 0.50 μm. In one preferred embodiment, the Ge₁₋ₓSnₓ layer can have a thickness of about 0.1 μm to about 1.0 μm.

Alternatively, in a preferred embodiment of any of the preceding embodiments, the Ge₁₋ₓSnₓ layer can have a thickness of greater than about 5 μm. For example, the Ge layer and/or the first active block can have a thickness of about 5 μm to about 100 μm; or about 5 μm to about 50 μm; or about 5 μm to about 25 μm. In one preferred embodiment, the Ge layer and/or the first active block can have a thickness of about 5 μm to about 10 μm.

The Ge_{1-x-y}SiₓSn_{y} layers in the preceding embodiments can comprise any of the Ge_{1-x-y}SiₓSn_{y} layers as discussed above.

In a preferred embodiment of any of the preceding embodiments, each III-V active block formed over the buffer region can independently comprise a p-n junction or p-i-n junction. Therein, each III-V active block may comprise a binary, tertiary, quaternary or higher (InGaAl)(AsSbP) semiconductor. In certain preferred embodiments, the plurality of III-V active blocks comprises a first active block formed over the buffer region, wherein the first active block formed over the buffer region comprises p-doped, n-doped, or intrinsic (Al_{z}Ga_{1-z}As)ₐ(InP)₁₋ₐ (e.g., (Al_{0.1}Ga_{0.9}As)_{0.65}(InP)_{0.35}), or mixtures thereof, wherein a is between 0 and 1, inclusive, and z is between 0 and 1, inclusive.

In certain preferred embodiments, the plurality of III-V active blocks comprises a first active block formed over the buffer region, wherein the first active block formed over the buffer region comprises p-doped, n-doped, or intrinsic (Al_{z}Ga_{1-z}As)ₐ(InP)₁₋ₐ (e.g., (Al_{0.1}Ga_{0.9}As)_{0.65}(InP)_{0.35}), or mixtures thereof, wherein a is between 0 and 1, inclusive, and z is between 0 and 1, inclusive, wherein the first active block is lattice-matched or pseudomorphically strained with respect to the buffer region and/or the Ge layer.

In certain preferred embodiments, the plurality of III-V active blocks comprises a first active block formed over the buffer region, wherein the first active block formed over the buffer region comprises p-doped, n-doped, or intrinsic (Al_{z}Ga_{1-z}As)ₐ(InP)₁₋ₐ (e.g., (Al_{0.1}Ga_{0.9}As)_{0.65}(InP)_{0.35}), or mixtures thereof, wherein a is between 0.45 and 1, inclusive, and z is between 0 and 1, inclusive, wherein the first active block is lattice-matched or pseudomorphically strained with respect to the buffer region and/or the Ge layer.

In certain other preferred embodiments, the plurality of III-V active blocks comprises (i) a first active block formed over the buffer region, wherein the first active block comprises p-doped, n-doped, or intrinsic (Al_{z}Ga_{1-z}As)ₐ(InP)₁₋ₐ (e.g., (Al_{0.1}Ga_{0.9}As)_{0.65}(InP)_{0.35}, or mixtures thereof, wherein a is between 0 and 1 and z is between 0 and 1, inclusive; and (ii) a second active block, formed over the first active block, comprising p-doped, n-doped, or intrinsic (AlⱼIn₁₋ⱼP)_{b}(GaP)_{1-b}, (e.g., (Al_{0.26}In_{0.74}P)_{0.90}(GaP)_{0.10}), or mixtures thereof, wherein b is between 0 and 1, inclusive, and j is between 0 and 1, inclusive.

In certain other preferred embodiments, the plurality of III-V active blocks comprises (i) a first active block formed over the buffer region, wherein the first active block comprises p-doped, n-doped, or intrinsic (Al_{z}Ga_{1-z}As)ₐ(InP)₁₋ₐ (e.g., (Al_{0.1}Ga_{0.9}As)_{0.65}(InP)_{0.35}, or mixtures thereof, wherein a is between 0 and 1 and z is between 0 and 1, inclusive; and (ii) a second active block, formed over the first active block, comprising p-doped, n-doped, or intrinsic (AlⱼIn₁₋ⱼPb(GaP)_{1-b}, (e.g., (Al_{0.26}In_{0.74}P)_{0.90}(GaP)_{0.10}), or mixtures thereof, wherein b is between 0 and 1, inclusive, and j is between 0 and 1, inclusive, wherein the first and second active blocks are lattice-matched or pseudomorphically strained with respect to the buffer region and/or the Ge layer.

In certain other preferred embodiments, the plurality of III-V active blocks comprises (i) a first active block formed over the buffer region, wherein the first active block comprises p-doped, n-doped, or intrinsic (Al_{z}Ga_{1-z}As)ₐ(InP)₁₋ₐ (e.g., (Al_{0.1}Ga_{0.9}As)_{0.65}(InP)_{0.35}, or mixtures thereof, wherein a is between 0.45 and 1 and z is between 0 and 1, inclusive; and (ii) a second active block, formed over the first active block, comprising p-doped, n-doped, or intrinsic (AlⱼIn₁₋ⱼP)_{b}(GaP)_{1-b}, (e.g., (Al_{0.26}In_{0.74}P)_{0.90}(GaP)_{0.10}), or mixtures thereof, wherein b is between 0 and 1, inclusive, and j is between 0 and 1, inclusive, wherein the first and second active blocks are lattice-matched or pseudomorphically strained with respect to the buffer region and/or the Ge layer.

Further, in a preferred embodiment of any of the preceding embodiments, a tunnel junction may be formed between each of the active blocks (e.g., between each of the plurality of III-V active blocks). In the semiconductor structures described above, all the active blocks, in combination, can absorb light having a wavelength ranging from about 350 nm to about 1800 nm.

In a preferred embodiment of any of the preceding embodiments, the Si substrate can comprise or consist essentially of Si, n-doped Si, p-doped Si, semi-insulating Si, intrinsic Si, or compensated Si. In certain preferred embodiments, the Si substrate comprises or consists essentially of an intrinsic Si substrate, a compensated Si substrate, a semi-insulating Si substrate, or a silicon-on-insulator (SOI) substrate (e.g., single-faced Si surface layer on SiO₂ or double-faced Si with a first and second Si surface layer each over an embedded SiO₂ layer). In another preferred embodiment, the Si substrate comprises or consists essentially of Si(100), n-doped Si(100), p-doped Si(100), semi-insulating Si(100), compensated Si(100), or intrinsic Si(100). In certain preferred embodiments, the Si substrate can be p-doped. In certain other preferred embodiments, the Si substrate can be n-doped.

Further, the Si substrate, in a preferred embodiment of any of the preceding embodiments, can have a diameter of at least 3 inches, for example, at least 6 inches. For example, the Si substrate can have a diameter of about 6 in. to about 12 in. In other examples, the Si substrate can have a diameter of about 8 in. to about 12 inches.

In a second aspect, the invention provides methods for forming a semiconductor structure comprising forming a buffer region directly over a Si substrate; and forming a plurality of III-V active blocks over the buffer region, wherein the buffer region comprises (a) a Ge layer having a threading dislocation density below 10⁵/cm²′ wherein the Ge layer is formed directly over the Si substrate, and a Ge_{1-x-y}SiₓSn_{y} layer formed over the Ge layer; or (b) a Ge₁₋ₓSnₓ layer formed directly over the Si substrate and a Ge_{1-x-y}SiₓSn_{y} layer formed over the Ge₁₋ₓSnₓ layer; and the first III-V active block formed over the buffer region is lattice matched or pseudomorphically strained to the buffer region.

Each of the buffer region and/or the plurality of III-V active blocks can be independently formed by gas source molecular beam epitaxy, chemical vapor deposition, plasma enhanced chemical vapor deposition, laser assisted chemical vapor deposition, and atomic layer deposition. In one embodiment, the buffer region and/or the plurality of III-V active blocks can be formed by chemical vapor deposition or molecular beam epitaxy.

In particular, each of the preceding materials can prepared by chemical vapor deposition of chemical sources such as, but not limited to, digermane silylgermane, trisilane, stannane, or mixtures thereof. Further, the Si: Sn concentration in each of the preceding material can be tuned, for example, by relative ratios of trisilane and stannane utilized as the sources of Si and Sn respectively.

In one preferred embodiment, a Ge layer having a threading dislocation density below 10⁵/cm² is formed directly over the Si substrate. Pure Ge films can be grown directly over Si substrates, for example, via chemical vapor deposition, (see, Wistey et al., Appl. Phys. Lett. 2007, 90, 082108; Fang et al., Chem. Mater. 2007, 19, 5910-25; and U.S. patent application Ser. No. 12/133,225, entitled, “Methods and Compositions for Preparing Ge/Si Semiconductor Substrates,” filed 4 Jun. 2008, each of which are hereby incorporated by reference in their entirety). In one preferred embodiment, the Ge layer can be formed by contacting the Si substrate with a chemical vapor comprising an admixture of (a) (H₃Ge)₂CH₂, H₃GeCH₃, or a mixture thereof; and (b) Ge₂H₆, wherein Ge₂H₆ is in excess.

In one preferred embodiment, the admixture can be an admixture of (GeH₃)₂CH₂ and Ge₂H₆ in a ratio of between 1:10 and 1:20. In another preferred embodiment, the admixture can be an admixture of GeH₃CH₃ and Ge₂H₆ in a ratio of between 1:5 and 1:30. In another preferred embodiment, the admixture can be an admixture of GeH₃CH₃ and Ge₂H₆ in a ratio of between 1:5 and 1:20. In yet another preferred embodiment, the admixture can be an admixture of GeH₃CH₃ and Ge₂H₆ in a ratio of between 1:21 and 1:30. In yet another preferred embodiment, the admixture can be an admixture of GeH₃CH₃ and Ge₂H₆ in a ratio of between 1:15 and 1:25.

In a further preferred embodiment, the admixture can be an admixture of a combination of (GeH₃)₂CH₂ and GeH₃CH₃ at a 1:5 to 1:30 ratio with Ge₂H₆. In another preferred embodiment, the admixture can be an admixture of a combination of (GeH₃)₂CH₂ and GeH₃CH₃ at a 1:5 to 1:20 ratio with Ge₂H₆. In another preferred embodiment, the admixture can be an admixture of a combination of (GeH₃)₂CH₂ and GeH₃CH₃ at a 1:21 to 1:30 ratio with Ge₂H₆. In another preferred embodiment, the admixture can be an admixture of a combination of (GeH₃)₂CH₂ and GeH₃CH₃ at a 1:15 to 1:25 ratio with Ge₂H₆. In various non-limiting preferred embodiments, the admixtures can be in ratios between 1:5 and 1:15, between 1:5 and 1:10, between 1:10 and 1:20, between 1:0 and 1:15, between 1:21 and 1:30, between 1:22 and 1:30, between 1:23 and 1:30, between 1:24 and 1:30, between 1:25 and 1:30, between 1:26 and 1:30, between 1:27 and 1:30, between 1:28 and 1:30, or between 1:29 and 1:30; or admixtures in ratios of 1:5, 1:6, 1:7, 1:8, 1:9; 1:10; 1:11:, 1:12; 1:13; 1:14; 1:15.1:16, 1:17, 1:18, 1:19, 1:20, 1:21, 1:22, 1:23, 1:24, 1:25, 1:26, 1:27, 1:28, 1:29, or 1:30.

In various preferred embodiments, the gaseous precursors are provided in substantially pure form in the absence of diluants. In a further preferred embodiment, the gaseous precursors are provided as a single gas mixture. In another preferred embodiment, the gaseous precursors are provided intermixed with an inert carrier gas. In this embodiment, the inert gas can be, for example, H₂ or N₂ or other carrier gases that are sufficiently inert under the deposition conditions and process application.

n-type Ge layers can be prepared by the controlled substitution of, for example, P, As, or Sb atoms in the Ge lattice according to methods familiar to those skilled in the art. One example includes, but is not limited to, the use of P(SiH₃)₃ to provide n-doping through controlled substitution of P atoms.

p-Type Ge layers can be prepared by the controlled substitution of B, Al, Ga, or In atoms in the Ge lattice according to methods familiar to those skilled in the art. One example includes, but is not limited to, B substitution can be affected by use of B₂H₆. Such p- and n-doping methods can provide Ge layers having carrier concentrations in the range of about 10¹⁷ cm⁻³ to about 10²¹ cm⁻³; or about 10¹⁷ cm⁻³ to about 10¹⁹ cm⁻³.

In a further preferred embodiment, the gaseous precursor is introduced by gas source molecular beam epitaxy at between at a temperature of between about 350° C. and about 450° C., more preferably between about 350° C. and about 430° C., and even more preferably between about 350° C. and about 420° C., about 360° C. and about 430° C., about 360° C. and about 420° C., about 360° C. and about 400° C., or about 370° C. and about 380° C. Practical advantages associated with this low temperature/rapid growth process include (i) short deposition times compatible with preprocessed Si wafers, (ii) selective growth for application in high frequency devices, and (iii) negligible mass segregation of dopants, which is particularly critical for thin layers.

In various further preferred embodiments, the gaseous precursor is introduced at a partial pressure between about 10⁻⁸ Torr and about 1000 Torr. In one preferred embodiment, the gaseous precursor is introduced at between about 10⁻⁷ Torr and about 10⁻⁴ Torr gas source molecular beam epitaxy or low pressure CVD. In another preferred embodiment, the gaseous precursor is introduced at between about 10⁻⁷ Torr and about 10⁻⁴ Torr for gas source molecular beam epitaxy. In yet another preferred embodiment, the gaseous precursor is introduced at between about 10⁻⁶ Torr and about 10⁻⁵ Torr for gas source molecular beam epitaxy.

In another preferred embodiment, a Ge₁₋ₓSnₓ layer is formed directly over the Si substrate and a Ge_{1-x-y}SiₓSn_{y} layer is formed over (e.g., directly over) the Ge₁₋ₓSnₓ layer. Methods for preparing the Ge₁₋ₓSnₓ layers can be found, for example, in U.S. Patent Application Publication No. US2007-0020891-A1, which is hereby incorporated by reference in its entirety. For example, the Ge₁₋ₓSnₓ layer can be formed by contacting the Si substrate with a chemical vapor comprising Ge₂H₆ and SnD₄. In such embodiments, the chemical vapor can further comprise H₂.

After growth of each desired Ge₁₋ₓSnₓ layer, the semiconductor structure can be subject to a post-growth Rapid Thermal Annealing treatment. For example, the structure can be heated to a temperature of about 750° C. and held at such temperature for about 1 to about 10 seconds. The structure can be cycled multiple times between the temperature utilized for GeSn deposition (about 300° C. to about 350° C.) to about 750° C. For example, the structure can be cycled from 1 to 10 times, or 1 to 5 times, or 1 to 3 times.

n-Type Ge₁₋ₓSnₓ layers can be prepared by the controlled substitution of P, As, or Sb atoms in the Ge₁₋ₓSnₓ lattice according to methods known to those skilled in the art. One example includes, but is not limited to, the use of As(GeH₃)₃, which furnishes structurally and chemically compatible AsGe₃ molecular cores (see, Chizmeshya et al., Chem. Mater. 2006, 18, 6266; and US Patent Application Publication No. 2006-0134895-A1, each of which are hereby incorporated by reference in their entirety) can give n-type Ge₁₋ₓSnₓ layers. In another example, P(SiH₃)₃ can provide n-doping through controlled substitution of P atoms.

p-Type Ge₁₋ₓSnₓ layers can be prepared by the controlled substitution of B, Al, Ga, or In atoms in the Ge₁₋ₓSnₓ lattice according to methods known to those skilled in the art. One example includes, but is not limited to, conventional CVD reactions of SnD₄, Ge₂H₆ and B₂H₆ at low temperatures. Such p- and n-doping methods can provide GeSn layers having carrier concentrations in the range of about 10¹⁷ cm⁻³ to about 10²¹ cm⁻³; or about 10¹⁷ cm⁻³ to about 10¹⁹ cm⁻³.

Methods for preparing the Ge_{1-x-y}SiₓSn_{y} layer can be found, for example, in U.S. Patent Application Publication No. US2006-0163612-A1 which is hereby incorporated by reference in its entirety. For example, the Ge_{1-x-y}SiₓSn_{y} layer can be formed by contacting the Ge₁₋ₓSnₓ layer with a chemical vapor comprising H₃SiGeH₃ and SnD₄. In such embodiments, the chemical vapor can further comprise H₂.

n-type Ge_{1-x-y}SiₓSn_{y} layers can be prepared by the controlled substitution of P, As, or Sb atoms in the Ge_{1-x-y}SiₓSn_{y} lattice according to methods known to those skilled in the art. One example includes, but is not limited to, the use of As(GeH₃)₃, which furnishes structurally and chemically compatible AsGe₃ molecular cores can give n-type Ge_{1-x-y}SiₓSn_{y} layers. In another example, P(SiH₃)₃ can provide n-doping through controlled substitution of P atoms.

p-Type Ge_{1-x-y}SiₓSn_{y} layers can be prepared by the controlled substitution of B, Al, Ga, or In atoms in the Ge_{1-x-y}SiₓSn_{y} lattice according to methods known to those skilled in the art. One example includes, but is not limited to, p-Type Ge_{1-x-y}SiₓSn_{y} layers can be prepared via conventional CVD reactions of SnD₄, Ge₂H₆ and B₂H₆ at low temperatures.

Such p- and n-doping methods can provide Ge_{1-x-y}SiₓSn_{y} layers having carrier concentrations in the range of about 10¹⁷ cm⁻³ to about 10²¹ cm⁻³; or about 10¹⁷ cm⁻³ to about 10¹⁹ cm⁻³.

The methods of the second aspect of the invention can be used for preparing the semiconductor structures according to the first aspect of the invention and any embodiments thereof.

In a third aspect, the invention provides Ge_{1-x-y}SiₓSn_{y} alloys that are lattice matched or pseudomorphically strained to Ge, wherein x is about 0.07 to about 0.42 and y is about 0.01 to about 0.20. In one preferred embodiment of the third aspect, x is about 0.19 to about 0.37. In other preferred embodiments, y is about 0.02 to about 0.12 or about 0.05 to about 0.09.

In a fourth aspect, the invention provides Ge_{1-x-y}SiₓSn_{y} alloys, lattice matched or pseudomorphically strained to Ge, having a bandgap of about 0.80 eV to about 1.40 eV or about 0.90 eV to about 1.35 eV. In one preferred embodiment, the bandgap is about 0.95 eV to about 1.20 eV or about 1.05 eV to about 1.20 eV. In certain preferred embodiments, x is about 0.07 to about 0.42 and y is about 0.01 to about 0.20. In another preferred embodiment of the fourth aspect, x is about 0.19 to about 0.37. In other embodiments, y is about 0.02 to about 0.12 or about 0.05 to about 0.09.

In a fifth aspect, the invention provides Ge_{1-x-y}SiₓSn_{y} alloys of the formula Ge_{1-X}(Si_{β}Sn_{1-β})_{X} where β is about 0.79 and X is a value greater than 0 and less than 1. In one preferred embodiment, X can be between about 0.05 and about 0.95. In another preferred embodiment, X can be between about 0.05 and about 0.90. In another preferred embodiment, X can be between about 0.05 and about 0.85. In another preferred embodiment, X can be between about 0.05 and about 0.80. In another preferred embodiment, X can be between about 0.05 and about 0.75. In another preferred embodiment, X can be between about 0.05 and about 0.70. In another preferred embodiment, X can be between about 0.05 and about 0.65. In another preferred embodiment, X can be between about 0.05 and about 0.60. In another preferred embodiment, X can be between 0.05 and about 0.55. In another preferred embodiment, X can be between about 0.05 and about 0.50.

### EXAMPLES

### Example 1

### Ge/Si(100) Structures and Templates

Pure Ge films can be formed directly on Si substrates with unprecedented control of film microstructure, morphology, purity and optical properties can be grown via CVD (see, Wistey et al., Appl. Phys. Lett. 2007, 90, 082108; and Fang et al., Chem. Mater. 2007, 19, 5910-25, which is hereby incorporated by reference in its entirety). In preceding method, growth is conducted at low temperatures (about 350° C. to about 420° C.) on a single wafer reactor configuration at 10⁻⁵-10⁻⁴ Torr, in the absence of gas phase reactions using molecular mixtures of Ge₂H₆ and small amounts of highly reactive (GeH₃)₂CH₂ or GeH₃CH₃ organometallic additives.

The optimized molar ratios of these compounds have enabled layer-by-layer growth at conditions compatible with selective growth, which has recently been demonstrated by depositing patterned Ge “source/drain” structures in prototype devices. The driving force for this reaction mechanism is the facile elimination of extremely stable CH₄ and H₂ byproducts, consistent with calculated chemisorption energies and surface reactivities.

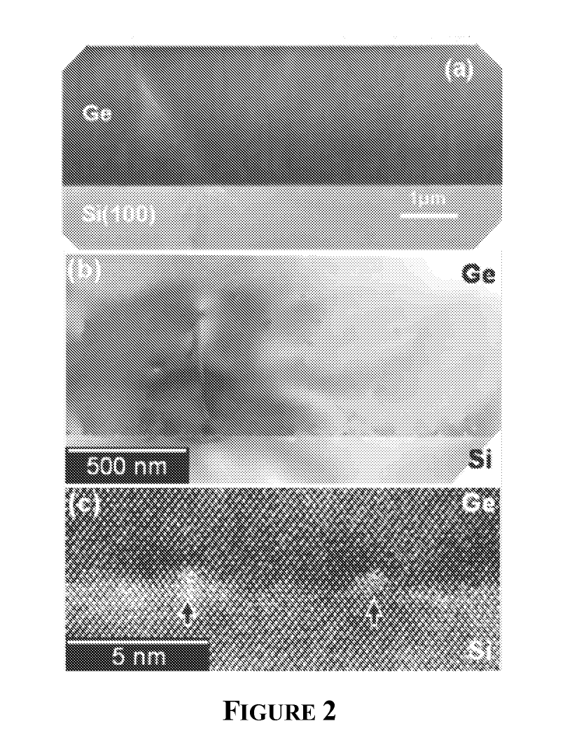

Using this approach atomically smooth (AFM RMS ˜0.2 nm) and stress-free Ge films have been produced with dislocation densities less than 10⁵ cm⁻², two orders of magnitude lower than those attainable from the best competing processes. The full relaxation in the films is readily achieved via formation of Lomer dislocations confined to the Ge/Si interface (FIG. 2) and this allows film dimensions approaching bulk values to be achieved on a Si substrate, for the first time. These defects are found to alleviate the interface strain associated with the pseudomorphic growth and suppress the propagation of dislocation cores throughout the layer as shown in etch-pit density characterizations.

XTEM micrographs (FIG. 2) show two representative layers with thickness up to several microns, which have been grown at extremely high growth rates of 100 nm/min using a 15:1 molar ratio of Ge₂H₆:(GeH₃)₂CH₂, indicating that the approach is viable from a large scale commercial perspective. Raman studies of these samples confirm that the materials are virtually stress- and defect-free. Their photoreflectance signal is comparable to that of bulk Ge, and in the most perfectly relaxed films we have also observed photoluminescence, a testament to their high crystal quality, indicating their tremendous potential as new active layers material. The desirable growth conditions, low dislocations densities and superior film morphology make Ge films grown by this method an ideal platform for producing perfectly crystalline and fully epitaxial III-V epilayers suitable for photovoltaic applications.

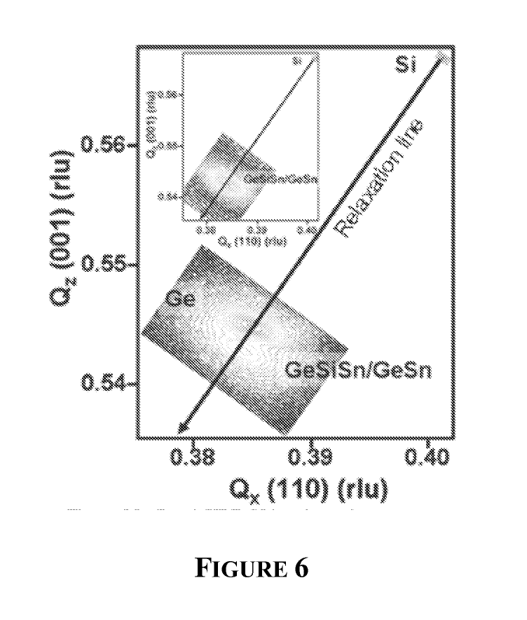

In particular, we have demonstrated growth of thick Ge films with atomically flat surfaces, strain free states and record low dislocation densities (less than 10⁵/cm²) for applications as photovoltaic junctions integrated with large area Si substrates. The results indicated that these materials can be grown with thicknesses of ˜5 μm (FIG. 6) and there appears to be no upper limit to the thickness that can be achieved using our method. This achievement has immediate implications for photovoltaics due to the potential for replacing the costly and heavy Ge substrates. In this regard FIG. 6 (inset) shows that a 5 μm Ge film absorbs 85% of the GaAs-filtered light relative to the absorption by a commercial Ge substrate.

We have demonstrate the fabrication of Ge layers on large scale Si platforms with 3-4″ diameters with superior morphology and microstructure. Here the Ge buffer layers were first grown directly on Si at 350° C. with nominal thickness of about 500 nm to about 700 nm using deposition molecular mixtures of Ge₂H₆ and small amounts of (GeH₃)₂CH₂. The layers subsequently produced were found to exhibit strain relaxed microstructures, extremely low defect densities of ˜10⁴/cm², atomically flat surfaces, and Ge layers approaching 5 microns in thickness were manufactured for the first time.

### Example 2

### Doped Ge/Si(100)

The n-type doping of the Ge layers grown directly on Si can be conducted using proven protocols that have already led to the successful doping of the Ge₁₋ₓSnₓ alloys. These utilize As, Sb, P custom prepared hydride compounds such as As(GeH₃)₃, P(GeH₃)₃ and Sb(GeH₃)₃ molecules. These are co-deposited with mixtures of digermane to form Ge films incorporating the appropriate carrier type and level. In the case of As we have able to introduce free carrier concentrations as high as 10²⁰/cm³ in Ge₁₋ₓSnₓ via deposition of As(GeH₃)₃. These carbon-free hydrides are ideal for low temperature, high efficiency doping applications. They are designed to furnish a structural Ge₃As unit resulting inhomogeneous substitution at high concentrations without clustering or segregation. For p-type doping suitable concentrations of gaseous B₂H₆ can be mixed with the Ge precursors and reacted to obtain the desired doping level.

In one example, p-type Ge layers with thickness of about 0.7 μm to about 1.5 μm were grown using a virtually identical approach as described in Example 1, utilizing reactions of Ge₂H₆, (GeH₃)₂CH₂ and B₂H₆ to obtain carrier concentrations in the range of 10¹⁷ cm⁻³ to 10¹⁹ cm⁻³. The n-type counterparts were deposited on undoped Ge buffers using the (SiH₃)₃P compound as the source of P atoms yielding active carrier concentrations up to 3×10¹⁹/cm³. The secondary ion spectrometry (SIMS) profiles of the latter films showed a sharp transition at the i-Ge/n-Ge interface suggesting that the formation of a full p-i-n device structure is within reach.

The B and P concentration and corresponding transport properties in the doped samples was independently determined by SIMS and ellipsometry and the results indicated a close agreement between the two methods. The films exhibited atomically flat surfaces (RMS ˜2 Å) and fully relaxed, highly aligned structures as shown by XRD and XTEM measurements.

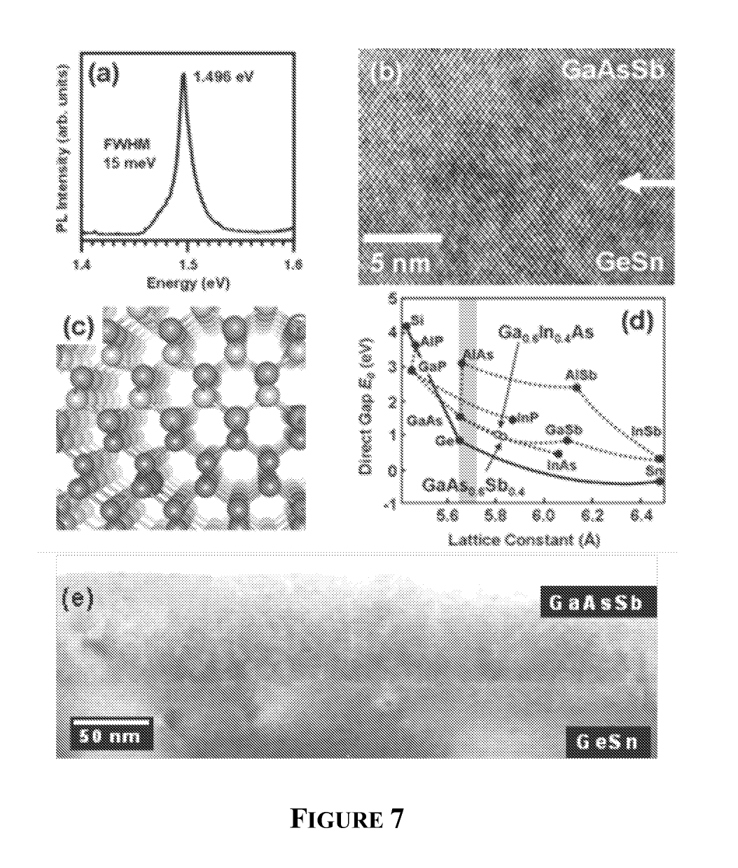

This successful demonstration of p- and n-doping was followed by attempts to assemble multilayer structures in p-i-n geometry. A typical sample consisted of about 500 nm p-type initial layer and an about 1600 nm intrinsic epilayer and exhibited superior structural and morphological properties. For example, the FWHM of the (004) reflection was ˜0.05° (180 arcsecs), unprecedented for Ge film growth on mismatched Si substrates. SIMS profiles showed an abrupt transition between p-type and intrinsic Ge layer regions as shown in FIG. 7 indicating no interdiffusion of B atoms across the common heterojunction.

### Example 3

### Optoelectronic Ge_{1-y}Sn_{y} Alloys

From a fundamental view point Ge_{1-y}Sn_{y} alloys on their own right are intriguing IR materials that undergo an indirect-to-direct band gap transition with variation of their strain state and/or compositions. They also serve as versatile, compliant buffers for the growth of II-VI and III-V compounds on Si substrates.

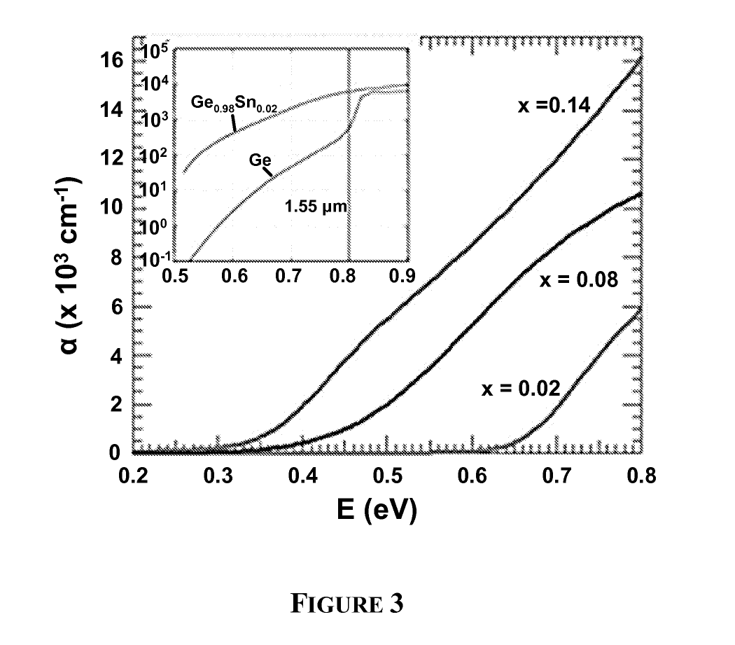

The fabrication of the Ge_{1-y}Sn_{y} materials directly on Si wafers has recently been reported using a specially developed CVD method involving reactions of Ge₂H₆ with SnD₄ in high purity H₂ (about 10%). Thick and atomically flat films are grown at 250° C. to about 350° C. and possess low densities of threading dislocations (about 10⁵ cm⁻²) and high concentrations of Sn atoms up to about 20%. Since the incorporation of Sn lowers the absorption edges of Ge, the Ge_{1-y}Sn_{y} alloys are attractive for detector and photovoltaic applications that require band gaps lower than that of Ge (0.80 eV). The absorption coefficient of selected Ge₁₋ₓSnₓ samples, showing high absorption well below the Ge band gap, is show in FIG. 3 (see, D'Costa et al., Phys. Rev. B 2006, 73, 125207).

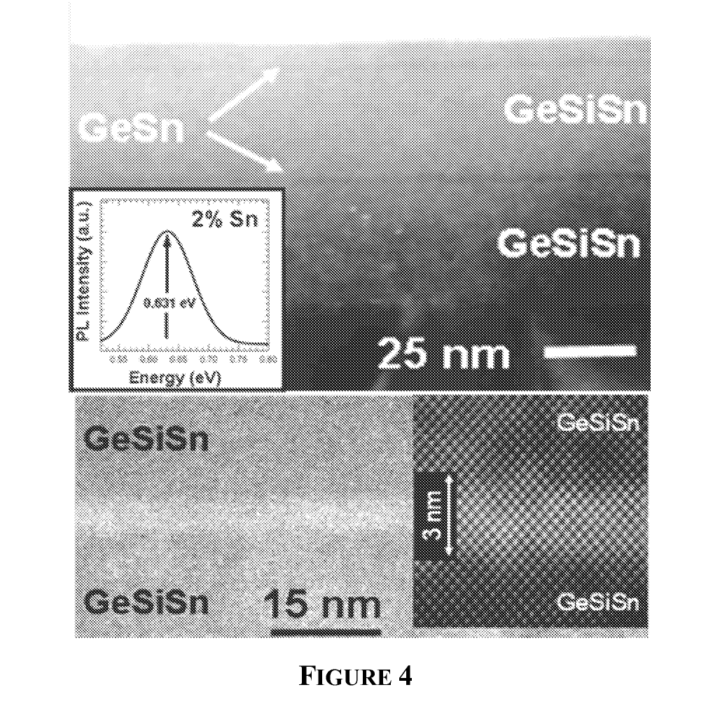

In addition, photoluminescence has been observed near the expected band gap wavelength in Ge_{1-x-z}SiₓSn_{z}/Ge_{1-y}Sn_{y}/Ge_{1-x-y}SiₓSn_{y} lattice matched structures (FIG. 4). The active Ge₁₋ₓSnₓ layer in these arrays is ensconced within the higher band gap Ge_{1-x-z}SiₓSn_{z} barrier layers to increase the radiative recombination rate in the thin films. Work to date has demonstrated that the materials science is well developed and capable of deploying on a routine basis device quality films over a wide compositional range relevant to IR applications that are not accessible by the currently available photovoltaic cells based on pure Ge (see, Soref et al., J. Mater. Res. 2007, 22, 3281-91).

The compositional dependence of the Ge_{1-y}Sn_{y} band structure shows a dramatic reduction of the Ge-like optical transitions (the direct gap E₀, the split-off E₀+Δ₀ gap, and the higher-energy E₁, E₁+A₁, E_{0′} and E₂ critical points) as a function of Sn concentration (see, D'Costa, supra). With only 15 at. % Sn, the E₀ gap is reduced by half relative to that of pure Ge (0.80 eV). The concomitant lowering of the absorption edge implies that the relevant photovoltaic wavelengths can be covered with modest amounts of Sn in the alloys. Recent electrical measurements on prototype devices based on these materials are encouraging. Hall and IR ellipsometry indicate that the as-grown material is p-type, with hole concentrations in the 10¹⁶ cm⁻³ range. This background doping is found to be due to defects in the material and can be reduced using rapid thermal annealing. This occurs with a simultaneous increase in mobility to values above 600 cm²/V-sec, suggesting that the thermal treatment is truly removing the acceptor defects rather than creating compensating donor defects.

n- and p-Type layers can be prepared by the controlled substitution of active As atoms in the lattice is made possible by the use of As(GeH₃)₃, which furnishes structurally and chemically compatible AsGe₃ molecular cores (see, Chizmeshya et al., Chem. Mater. 2006, 18, 6266; and US Patent Application Publication No. 2006-0134895-A1, each of which are hereby incorporated by reference in their entirety). p-Type doping was conducted via conventional CVD reactions of SnD₄, Ge₂H₆ and B₂H₆ at low temperatures. Electrical measurements indicate that high carrier concentrations (˜3×10¹⁹ atoms/cm³) can be routinely achieved via these methods. The successful doping enabled fabrication of photodetectors based on simple PIN Ge_{1-y}Sn_{y} structures. The test results so far suggest that the material is viable from a device perspective and suitable to be introduced into CMOS fabrication for integrated optoelectronics, including photovoltaics.

### Example 4

### Ge_{1-x-y}SiₓSn_{y} on Ge_{1-y} Sn_{y}-Buffered Substrates

Ge_{1-x-y}SiₓSn_{y} alloys grow on Ge_{1-y}Sn_{y}-buffered substrates, such as Si or Ge. They represent the first practical group-IV ternary alloy, since carbon can only be incorporated in minute amounts into the Ge—Si network to form SiGeC. Ge_{1-x-y}SiₓSn_{y} alloys can be kept lattice-matched to Ge by maintaining the Si:Sn ratio close to 4:1 (e.g., about 3:1 to 5:1).

The growth of Ge_{1-x-y}SiₓSn_{y} is accomplished by using the SiH₃GeH₃, (GeH₃)₂SiH₂, (GeH₃)₃SiH, and/or GeH₃SiH₂SiH₂GeH₃ hydrides as the source of the Si and Ge atoms. This general class of precursors furnishes building blocks of specifically tailored elemental contents that possess the necessary reactivity to readily form the desired metastable structures and compositions at low temperatures of about 300° C. to about 350° C. to form Ge-rich compositions with Si and Sn contents spanning from about 20% to about 37% and about 2% to about 12%, respectively, depending on the buffer layer lattice dimensions and the deposition conditions including reaction pressure, temperature and flow rates (see, Bauer et al., Appl. Phys. Lett. 2003, 83, 2163; and Aella et al., Appl. Phys. Lett. 2004, 84, 888). These results indicate that the Si concentration range can be significantly lower than the 50% value expected from the complete incorporation of the entire Si—Ge (50/50) molecular core of the SiH₃GeH₃ precursor into the film.

This discrepancy can be attributed to side reactions in which SiH₃GeH₃ partially dissociates via elimination of stable SiH₄ byproduct. The latter does not react any further particularly at the low growth temperature employed leading to the observed lower Si contents in the films. Thus the thermal dissociation of SiH₃GeH₃ likely proceeds by formation of higher order silygermanes with varying concentrations including (GeH₃)₂SiH₂ according to the reaction described by Eq 1:

2SiH₃GeH₃→(GeH₃)₂SiH₂+SiH₄ (Eq. 1)

In contrast, (GeH₃)₂SiH₂ reacts readily with SnD₄ at 350° C. to yield films with a Ge:Si ratio of 2:1, precisely matching that of the corresponding precursor. Using this approach affords synthetic flexibility that is impossible to obtain using either conventional CVD based on simple silanes and germanes, or by MBE using solid sources. We have been able to grow a host of device-quality samples in which the Ge_{y}Sn_{1-y}/Ge_{1-x-y}SiₓSn_{y} stack achieves a final strain state that minimizes the bilayer elastic energy, as if the films were effectively decoupled from the substrate (see, Tolle et al., Appl. Phys. Lett. 2006, 88, 252112). Accordingly, strained (tensile and compressive) as well as relaxed and lattice-matched Ge_{1-x-y}SiₓSn_{y} films can be produced on suitable Ge_{y}Sn_{1-y} templates. The intact incorporation of the molecular cores allows unparalleled compositional control by conferring the stoichiometry of the precursors directly to the films. The precursors can therefore be viewed as “nanofragments” of the target compounds, and the low temperature growth process represents a new form of materials nanosynthesis.

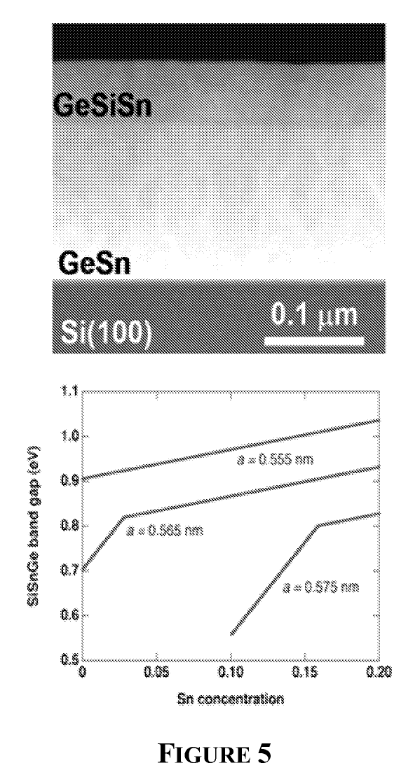

From the point of view of possible applications in optoelectronics, the most significant feature of the Ge_{1-x-y}SiₓSn_{y} ternary system is the capability of independent adjustment of lattice constant and band gap. In principle a wide range of band gaps can be achieved by adjusting the Si/Sn ratio in the alloy as illustrated in FIG. 5 which shows that for the same value of the lattice constant one can obtain band gaps differing by more than 0.2 eV, even if the Sn-concentration is limited to the range y<0.2. The continuum of band gaps for a fixed lattice constant can be used to develop a variety of devices from multicolor detectors to multiple junction photovoltaic cells. The lines in FIG. 5 were obtained by simple linear interpolation between the three elemental semiconductors Si, Ge and α-Sn. However, we have recently found that the compositional dependence of band gap and critical point energies is not linear. The energies for E₁, E₁+Δ₁, E_{0′} and E₂ show a negative deviation relative to the weighted average of the corresponding values in Si, Ge and α-Sn. These deviations from “Vegard's law” can be characterized by quadratic terms of the form -b_{AB}x_{A}x_{B} (where the bowing coefficients b_{AB}=[b_{siGe}, b_{GeSn}, b_{SiSn}] and x is the concentration). The results suggest that these bowing coefficients follow a simple scaling behavior with the electronegativity and size difference between Si, Ge, and α-Sn (see, D'Costa et al., Solid State Commun. 2006, 138, 309). This is remarkable from a fundamental viewpoint and very useful from a practical perspective. Critical for the photovoltaic applications will be to map the compositional dependence of the lowest direct band gap E₀, which approximately tracks the material's absorption edge.

Processes that have led to the successful doping of Ge₁₋ₓSnₓ layers (supra), such as the use of custom-prepared hydride compounds such as As(GeH₃)₃, P(GeH₃)₃, and Sb(GeH₃)₃, may be used for preparing n- and p-doped Ge_{1-x-y}SiₓSn_{y} layers.

We have applied this capability to produce light emitting quantum well structures comprised of Ge_{1-y}Sn_{y} active layers (E_{g}<0.70 eV) ensconced within higher gap Ge_{1-x-y}SiₓSn_{y} ternaries (E_{g}>1 eV) which serve as lattice matched barriers layers in prototype optoelectronic structures. This particular geometry is designed to keep any defects originating from the substrate interface away from the carriers in the Ge_{1-y}Sn_{y} active material.

The preceding Sn containing materials can also be used to manufacture versatile buffer layers for the subsequent growth of technologically relevant semiconductors to explore monolithic integration at conditions compatible with Si CMOS. In this regard, the Ge_{1-x-y}SiₓSn_{y} system provides unprecedented flexibility for lattice and thermal engineering that spans lattice constants from 5.4 Å to almost 6.5 Å and allows an independent adjustment of the coefficient of thermal expansion in the range of 2.5×10⁻⁶ K⁻¹ to 6.1×10⁻⁶ K⁻¹, particularly in ternary Ge_{1-x-y}SiₓSn_{y} alloys (see, Tolle, supra). We have fabricated such alloys with a lattice constant identical to that of Ge, as required to grow the four-junction solar cell designs described above. Our prior work has demonstrated unequivocally that Ge_{y}Sn_{1-y}/Ge_{1-x-y}SiₓSn_{y} templates exhibit versatile compliant behavior, which enables the integration needed to achieve the target heterostructures envisioned in this work.

Theoretical calculations show that the ideal band gaps for four-junction structures under AM1.5 direct normal solar irradiance are 0.53 eV, 1.13 eV, 1.55 eV, and 2.13 eV, respectively. (Marti and Araujo, Solar Energy Mater. and Solar Cells 1996, 43, 203) The theoretical efficiency limit for such combination is 70.7%. In principle, this band gap lineup can be obtained exactly by combining Ge₁₋ₓSnₓ, Ge_{1-x-y}SiₓSn_{y}, and III-V alloys. Using published band structure parameters for III-V materials (see, Vurgaftman et al., J. Appl. Phys. 2001, 89, 5815) a structure with the above bandgaps would consist of Ge_{0.91}Sn_{0.09} (first cell), Ge_{0.56}Si_{0.27}Sn_{0.17} (second cell), (Al_{0.1}Ga_{0.1}As)_{0.65}(InP)_{0.35} (third cell) and (Al_{0.26}In_{0.74}P)_{0.9}(GaP)_{0.1}(fourth cell).

Another typical stack grown upon Si involving all of the key group IV components, including Ge, Ge₁₋ₓSnₓ and Ge_{1-x-y}SiₓSn_{y} is shown in the XRD spectrum of FIG. 6. Here a representative lattice-matched Ge_{0.98}Sn_{0.02}/Ge_{0.60}Si_{0.30}Sn_{0.10} structure with thickness of 200/25 nm is grown strain-free on the underlying Si substrate. The relaxed lattice constant common to both layers is 5.674 Å, which is slightly larger than that of bulk Ge as grown. This platform is subsequently used as a buffer layer to grow a 0.7 μm thick Ge film. AFM and XRD analyses of the sample show that the terminal Ge layer is atomically flat (AFM, RMS 0.2 nm), fully coherent with the underlying buffer, and essentially relaxed and lattice-matched to the Ge_{0.98}Sn_{0.02}/Ge_{0.60}Si_{0.30}Sn_{0.10}. However, the in-plane lattice constant of the latter is observed to contract relative to its prior strain-free state, as expected, in response to the influence of the thick Ge film above. The final lattice dimensions of each component in the heterostructure have therefore adjusted to minimize the combined elastic energy of the entire stack indicating perfect compliant behavior. We note that this strain equilibration mechanism is commonly observed in structures based on the Ge_{1-x-y}SiₓSn_{y} system as reported previously in our studies. This lattice matching mechanism will be exploited to achieve seamless integration of the analogous proposed structures described in our technical objectives section. To the best of our knowledge, this is the only system offering such flexibility. Therefore, this technology has the potential to transform silicon into a universal platform for the development of broad range of devices featuring lattice-matched group-IV and III-V semiconductors, as needed for multijunction solar cells. We have already explored the growth of III-V materials on Sn-containing buffer layers. (see, Roucka et al., J. Appl. Phys. 2007, 101, 013518).

We used initially binary Ge₁₋ₓSnₓ alloys, which possess a set of unique properties which make them imminently suitable for integration of semiconductors with Si. They grow strain-free at low temperatures (about 250° C. to about 350° C.) compatible with selective growth and possess the necessary thermal stability for conventional semiconductor processing (up to 750° C. depending on composition). The films provide a cushioning effect that can absorb defects induced by differential strain. Typical defect densities below 10⁵ cm⁻² are routinely observed. The surfaces are atomically flat (no evidence for cross-hatch undulations) and can be readily cleaned by simple ex-situ chemical methods.

A series of uniform perfectly-epitaxial and strain-engineered InₓGa₁₋ₓAs and GaAs₁₋ₓSbₓ compositions (FIG. 7) have been produced across the entire alloy range that are grown on Ge_{1-y}Sn_{y} (y=0.02−0.10) buffers using MOCVD. Quantum well assemblies with a stacking sequence of AlGaAs/GaAs(QW)/AlGaAs/GeSn(buffer)/Si(100) have also been produced via MBE. These materials displayed high quality morphological and structural properties and show much less strain than those grown on conventional substrates. Their optical properties compare well with those measured in fully relaxed micrometer-thick layers grown on GaAs.

Advantageously, the increased lattice constant of Ge_{1-y}Sn_{y} relative to graded SiGe/Ge virtual substrates make it possible to form higher indium content InₓGa₁₋ₓAs layers as well as GaAs₁₋ₓSbₓ alloys with decreased strain. Additional layers (waveguiding, cladding, contact layers, etc) required by such devices (typically based on InGaAlAs materials) can also be grown with high quality (see, Roucka, supra).

### Example 5

### Ge_{1-x-y}SiₓSn_{y} on Ge-Buffered Substrates

The Ge_{1-x-y}SiₓSn_{y} alloys were also grown on Ge-buffered Si substrates. The structural and optical requirements for the new Ge/Ge_{1-x-y}SiₓSn_{y} junctions are achieved by tuning the Si/Sn ratios in the ternary to obtain alloys with lattice constants identical to that of elemental Ge (5.658 Å) and direct gaps in the vicinity of 1 eV. To match the Ge lattice constant, the Sn fraction in the alloy can in principle be increased from zero to a value of about 20%. Here we target a series of intermediate Ge-rich compositions with Sn contents in the range about 2% to about 11% that are expected to possess the desired band gaps. The necessary Si and Sn fractions in these are estimated using a linear interpolation of the Si, Ge and α-Sn lattice parameters (Vegard's Law).

To produce the heterostructures we first deposit enabling Ge buffer layers directly on Si at 350° C. in the nominal thickness range of about 200 nm to about 750 nm using a newly developed Ge-on-Si CVD method (see, Wistey et al., Appl. Phys. Lett. 2007, 90, 082108). These layers exhibit strain relaxed microstructures, extremely low defect densities of less than 10⁵/cm² (e.g., about 10⁴/cm²) and atomically flat surfaces thus providing an ideal platform for the subsequent formation of the SiGeSn overlayers. The latter films are grown ex situ via CVD using a slightly modified synthetic route than that previously employed for the analogous SiGeSn on GeSn buffered Si which involved binary mixtures of SiH₃GeH₃ and SnD₄.

In the present case, to achieve a higher degree of compositional control for lattice matching applications, and allow access to a wider range of Si compositions, we have developed an alternative approach based on appropriate stoichiometric mixtures involving SiH₂(SiH₃)₂ (trisilane) and/or SiH₃GeH₃, as the silicon source and Ge₂H₆ (digermane).

Trisilane contains highly reactive SiH₂ functionalities possessing fewer and far more reactive Si—H bonds enabling efficient epitaxy of Si based semiconductors than achievable using the conventional hydrides SiH₄ and Si₂H₆. Our recent studies have established that in general higher order silanes (containing SiH₂ groups) react more readily at low temperatures to form Si at a much higher growth rate compared to Si₂H₆ under the same conditions (see, Chizmeshya et al. J. Am. Chem. Soc. 2006, 128, 6919; Kress and Furthmuller, Phys. Rev. B 1996, 54, 11169). We note that at temperatures below 450° C. the activation energy of trisilane with respect to H₂ desorption is similar to that of SiH₃GeH₃ indicating that the reactivities of the two compounds are compatible throughout the growth temperature range of interest (see, Kress and Furthmuller, supra). Accordingly we utilize suitable mixtures involving SiH₃GeH₃ and/or SiH₂(SiH₃)₂ to obtain Si—Ge—Sn with precisely tuned Si concentrations in the final product for the first time. For example the synthesis of a typical low Sn concentration end member alloy, Ge_{0.90}Si_{0.08}Sn_{0.02}, is conducted via reactions of SnD₄ (as the source of Sn) with SiH₂(SiH₃)₂ and commercially available Ge₂H₆ as the sources of Si and Ge, respectively. We find that at the growth temperature of 350° C. pure SiH₂(SiH₃)₂ is sufficiently reactive to incorporate the relatively small target levels of Si between about 7% and about 10% thus circumventing the need for SiH₃GeH₃ which intrinsically delivers much higher Si contents than required under these conditions. In fact we have discovered that all of the reactions involving Ge₂H₆ and SiH₂(SiH₃)₂ are perfectly stoichiometric and proceed via the following general formula shown by Eq 2:

x[SiH₂(SiH₃)₂]+y[Ge₂H₆]→Si₃ₓGe_{2y}+(4x+3y)H₂ (Eq. 2)

This result indicates that SiH₂(SiH₃)₂ and Ge₂H₆ react completely via full incorporation of their entire molecular cores to yield compositions Si₃ₓGe_{2y} reflecting the stoichiometric ratio Ge/Si employed. This mechanism is consistent with our previous studies concerning the thermal activation of trisilane in which it was demonstrated that the unimolecular decomposition of the compound occurs readily at temperatures below 400° C. to deposit pure single crystal silicon films homoepitaxially on (100) surfaces.

As the Sn concentration in the ternary SiGeSn alloy increases to ≧5% the growth temperature can be reduced in the range of about 300° C. to about 330° C. to obtain single phase materials with complete Sn substitutionality. In practice, we have found that substitution of Sn in these materials is inversely related to the growth temperature. However, we observe that under these conditions (T<330° C.) trisilane is comparatively less reactive resulting in significantly reduced growth rates which either produced no measurable growth (below 310° C.) or yielded layers which are too thin for device applications but nevertheless sufficient for initial characterization of the alloys. Accordingly, to simultaneously achieve Sn and Si contents higher than about 5% and about 18% (respectively) in the vicinity necessary for lattice matching, the use of SiH₃GeH₃ in place of digermane becomes essential and the compound constitutes a source of both Ge and Si. In this regime a small addition of trisilane to the reaction medium can be used to enhance the Si content and thereby achieve fine-tuning of the target composition. The SiH₃GeH₃/SiH₂(SiH₃)₂ combination thus provides an unprecedented degree of compositional control and reproducibility particularly for samples requiring small changes (about 1% to about 2%) in Si content to achieve exact lattice matching as we discussed below.

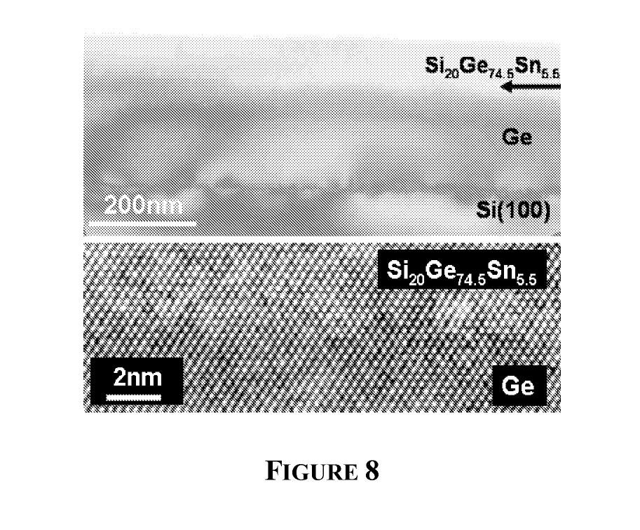

All Si/Ge/GeSiSn materials were characterized by extensive cross sectional transmission electron microscopy (XTEM), Rutherford backscattering (RBS), atomic force microscopy (AFM) and high resolution x-ray diffraction (HR-XRD) methods which in general revealed the formation of films with the desired compositions, near perfect microstructure and a smooth surface morphology. FIG. 8(a) shows a diffraction contrast XTEM micrograph of the entire heterostructure for a representative Ge/Ge_{0.745}Si_{0.20}Sn_{0.055} sample whose Si—Ge—Sn composition lattice matches the underlying Ge buffer. This sample was grown via reactions of SiH₃GeH₃ and SnD₄ at 330° C. at a growth rate of 1.5 nm per minute to 2 nm per minute to produce a final layer thickness of 80 nm. Note that the 300 nm buffer is devoid of threading dislocations, within the 1 μm field of view shown, and this in turn confers defect-free microstructure and a flat surface morphology onto the 80 nm thick SiGeSn overlayer. The smoothness of the as-grown films is confirmed by AFM scans which reveal an RMS roughness of 1 nm-2 nm for 20×20 μm² areas depending on the Sn content of the layer. The high resolution image in FIG. 8b indicates flawless registry across the Ge/SiGeSn interface at the atomic scale, as expected due to the precise lattice matching between the two materials. We note that under these growth conditions, all reactions of SiH₃GeH₃ and SnD₄ on Ge templates showed a remarkably propensity to (reproducibly) yield films with approximate stoichiometry in the vicinity of Ge_{0.75}S i_{0.20}Sn_{0.05}, in spite of substantial variations in the reactant ratios employed. Our observation suggests that the constituent atoms adopt specific stoichiometries that dimensionally match the underlying Ge substrate via a type of “compositional pinning” mechanism which promotes incorporation of about 20 at. % Si and about 5 at. % Sn in the film.

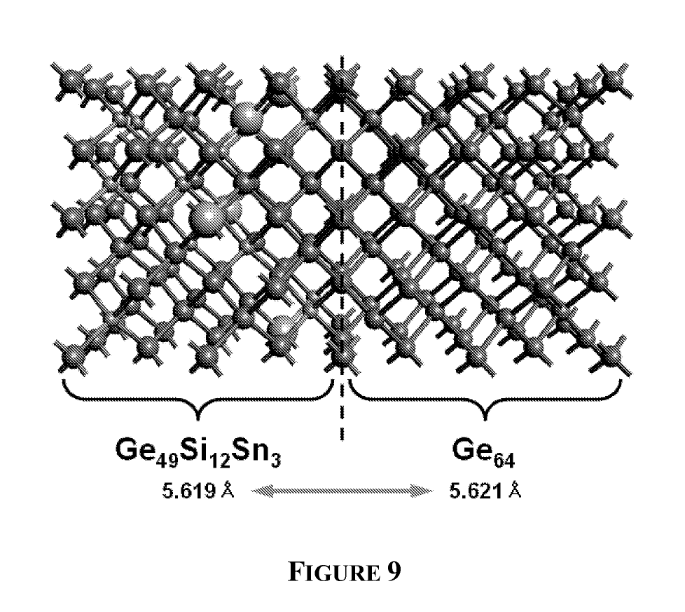

To elucidate this behavior we conducted a first principles DFT study of the Ge/Ge_{0.75}Si_{0.20}Sn_{0.05} interface structure using a Ge₆₄/Ge₄₉Si₁₂Sn₃ supercell representation, which corresponds to Ge_{0.76}Si_{0.19}Sn_{0.05}, closely matching the experimental structure. All supercell dimensions and atomic positions were simultaneously optimized to yield the ground state crystalline and electronic structure using the VASP code (see, Tolle et al., Appl. Phys. Lett. 2006, 89, 231924). The resulting in-plane lattice dimension for the zero-force configuration was found to be 5.620 Å, which corresponds to the average of the individually optimized values of pure Ge (5.621 Å) and the ternary alloy Ge₄₉Si₁₂Sn₃ (5.619 Å), indicating that the heterojunctions is stress-free. The slightly smaller equilibrium lattice constants obtained in our calculations are due to the well-known shortcoming of the local density approximation (LDA) which typically underestimates bond lengths by ˜1%-2%. Note that the Si and Sn atoms in the model shown in FIG. 9 were randomly distributed within the SiGeSn portion of the supercell. Models of this kind are currently being used to elucidate the role of interface chemical disorder on the electronic structure (band offsets, optical properties, etc).

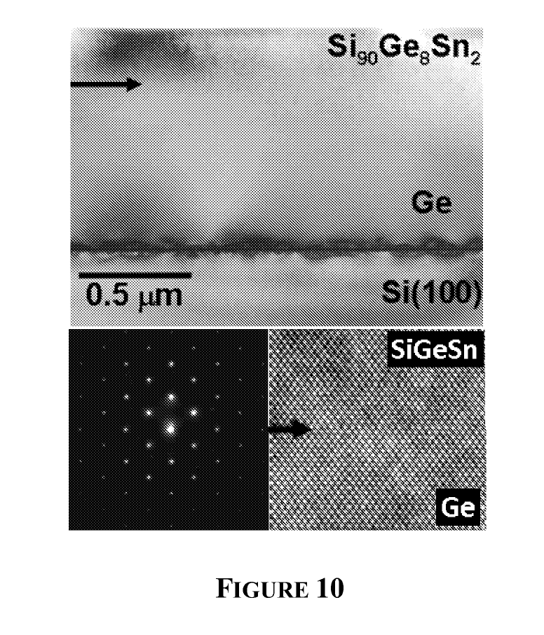

FIG. 10 shows the electron diffraction data of a 200 nm thick Ge_{0.90}Si_{0.08}Sn_{0.02} alloy (on a 750 nm Ge template) whose band gap and high thermal stability make it an ideal candidate for the photovoltaic applications described herein. In this case the material is grown at 350° C. via reactions of SnD₄ with a mixture of SiH₂(SiH₃)₂ and Ge₂H₆ in place of SiH₃GeH₃ which was used in the lower temperature synthesis described above. Note the complete absence of threading defects throughout the entire film within the 1.5 μm×1 μm field of view in the bright field micrograph (FIG. 10, top). High resolution images in (110) projection indicate perfect heteroepitaxy and selected area electron diffraction (SAED) patterns reveal a complete coincidence of the Ge and Ge_{0.90}Si_{0.08}Sn_{0.02} reciprocal lattice spots indicating that the corresponding cell dimensions are identical (FIG. 10, bottom).

The RBS analysis of the various samples produced in the study corroborated the XTEM observed thickness and also provided the Si, Sn and Ge concentrations. Ion channeling confirmed the full substitutionality of the Sn atoms in the Si—Ge lattice, and revealed full commensuration between the epilayer and the underlying Si(100). The ratio of the aligned over the random peak heights (χₘᵢₙ) is identical for all three constituent atoms and approaches the 4% limit in bulk Si, indicating a high degree of crystalline perfection in the samples.

HR XRD measurements were performed to confirm lattice matching, determine the precise in-plane and vertical unit cell parameters and study the temperature dependence of the heterostructures dimensions. The θ-2θ plots revealed only a single, sharp (004) peak indicating exact coincidence of the Ge and SiGeSn lattice dimensions. For a typical 400-750 nm thick film we obtain a (004) rocking curve with FWHM of 200 arcseconds indicating that the heterostructure is of high crystalline quality. The measured lattice parameters indicated complete absence of any compressive strain and in fact revealed that some of the structures are “over-relaxed”, exhibiting a slight tetragonal distortion corresponding to a slight tensile strain as high as 0.12%. For Sn and Si concentration ranging from about 2% to about 11% and about 8% to about 42%, respectively, the average room temperature values of the in-plane and vertical lattice parameters of the Ge/SiGeSn heterostructure are a₀=5.664±0.002 Å and c₀=5.652±0.001 Å.

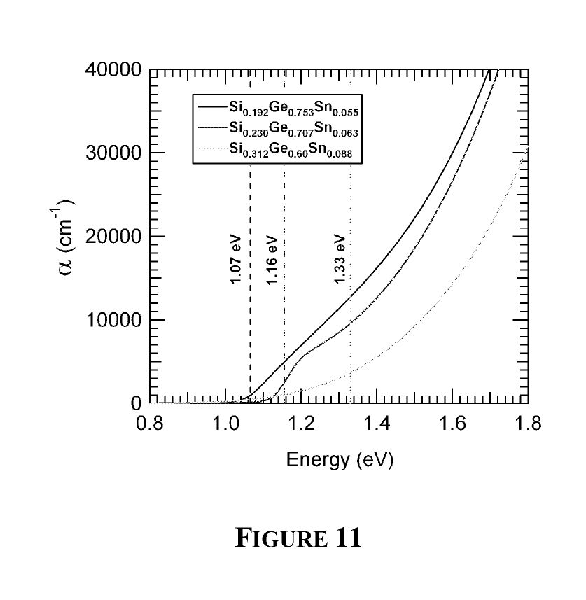

As can be seen in FIG. 11, which shows the absorption coefficient α as well as the position of the direct band edge (vertical lines) for families of Ge_{1-x-y}SiₓSn_{y} alloys deposited on Ge-buffered Si, Ge_{1-x-y}SiₓSn_{y} alloys having a tunable electronic structure have been prepared with a lattice constant matching that of pure Ge. This is the first time that the decoupling of lattice parameter and band structure is demonstrated for a group-IV alloy. The absorption coefficient can now be tuned to match the specific requirements of multijunction solar cell devices. In particular, a compound that is lattice-matched to Ge and possesses a direct band gap of approximately 1 eV has been actively sought as a fourth junction material to further improve the Ge/InGaAs/InGaP system, which currently represents the most efficient photovoltaic structure in the market. We believe that our Ge_{1-x-y}SiₓSn_{y} alloys may be the final solution to this urgent technological challenge.

The XRD data indicated that these lattice matched compositions follow closely Vegard's Law, which assumes a linear interpolation between the lattice parameters of Si, Ge and α-Sn according to α_{SiGeSn}(x,y)=(1−x−y)α_{Ge}+xα_{Si}+yα_{Si}, where α_{Si}=5.431 Å, α_{Ge}=5.658 Å and α_{Sn}=6.486 Å. In our earlier work we show that the bowing corrections in the Sn_{y}Ge_{1-y} and Si₁₋ₓGeₓ systems are positive and negative, respectively, so that their effects essentially cancel in the ternary. As mentioned above we find in practice that the Si content can be precisely tuned within the range of 1-2% to ensure a close matching of the ternary lattice dimension with that of Ge. For example, high resolution XRD data for the Ge/Si_{0.075}Sn_{0.020}Ge_{0.905} sample yields a relaxed lattice constant of 5.657 Å for both the buffer and the epilayer, in exact agreement with the value 5.657 Å obtained from Vegard's Law above. However for the Ge/Si_{0.095}Sn_{0.020}Ge_{0.885} sample, which is only slightly richer in silicon, the HR-XRD data reveals a significant splitting in the (004) and (224) peaks, indicating that the epilayer and the Ge buffer are no longer matched, although the nominal Sn content in both samples is the same (2%). While both samples were obtained using via reactions of Si₃H₈ (trisilane) and Ge₂H₆ (digermane) as shown in Eq. 2, the Si_{0.095}Sn_{0.020}Ge_{0.885} film was grown using a slightly higher Si₃H₈ concentration. The data collectively show that the Si/Sn ratios can remain close to 4 for lattice matching to occur as in the case of Si_{0.075}Sn_{0.020}Ge_{0.905}.

The application of these films in a practical device context also required a detailed understanding of the thermal response and stability of the structures. Accordingly we focused on the Ge_{0.90}Si_{0.08}Sn_{0.02} alloy with a band gap close to 0.90 eV. This material is expected to be the most thermally robust because of its relatively low Sn content. The sample was heated in situ on the XRD diffractometer to a series of temperatures in the range of 30° C.-700° C. using an Anton Paar high-temperature stage and the corresponding lattice parameters were recorded at each temperature. The heating was conducted under inert atmosphere conditions in a dynamic flow of UHP nitrogen at a 4 psi overpressure to avoid oxidation or decomposition of the layer. At each temperature the film was realigned using the Si (224) reflection to correct for any sample shift associated with the diffractometer stage expansion during heating. The lattice parameters of the film were determined from the (224) and (004) reciprocal space maps (RSM) and the data reveal that the residual strain essentially vanishes at 500° C. (c_{∥}=+0.01%). In addition the layers remain lattice matched to Ge from 30° C.-600° C. as evidenced by the persistent coincidence of the Ge and SiGeSn Bragg reflections.

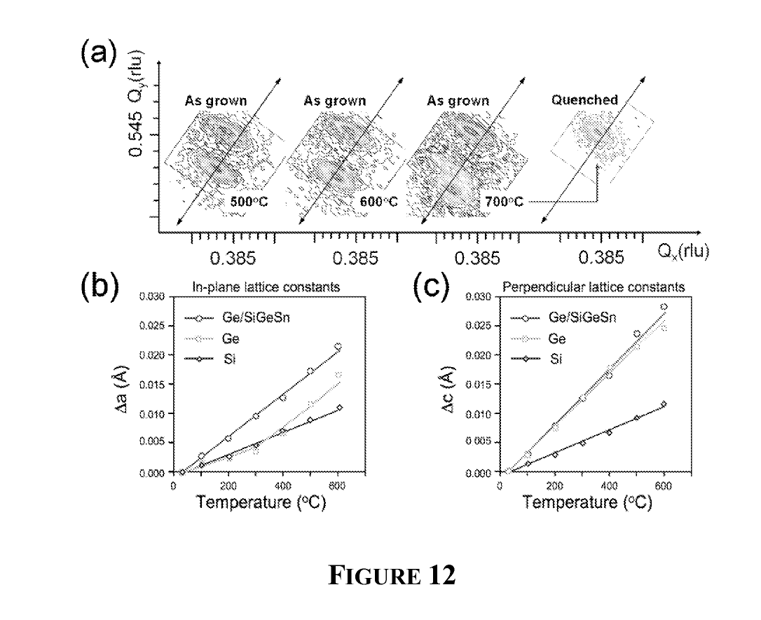

In FIG. 12, panel (a), we compare the (224) reflections obtained form the annealed sample at 500° C., 600° C., and 700° C. to that recorded at 30° C. for the as-grown sample. The plots show that the constituent Ge and Ge_{0.90}Si_{0.08}Sn_{0.02} layers are fully relaxed, coherent and lattice matched between 500° C.-600° C., as indicated by the overlap of the (224) peak maxima (lower spots in the reciprocal space maps) with the relaxation line (arrows) connecting the plot origin and the substrate Si (224) peak. At 700° C. (see third RSM panel) we observe a clear separation of the Ge and Ge_{0.90}Si_{0.08}Sn_{0.02} diffraction peaks indicating that the buffer becomes compressively strained with a=5.6812 Å and c=5.6878 Å as evidenced by the relaxation line passing slightly below center of the Ge (224) peak. The overlayer, however, remains cubic (a=5.6780 Å, c=5.6781 Å) and fully relaxed with respect to the substrate (relaxation line passes through the center of the peak). Prolonged heating of these samples at 700° C. in the XRD stage showed that the Ge_{0.90}Si_{0.08}Sn_{0.02} layer remain cubic and virtually coherent to the underlying Ge layer. This is the expected behavior at higher temperatures (above 600° C.) where the larger coefficient of thermal expansion (CTE) of Ge produces compression in the crystal. In comparison we note that the presence of a small amount of Si (˜8%) in Ge_{0.90}Si_{0.08}Sn_{0.02} slightly lowers the CTE of the alloy. To confirm that the observed decoupling of the Ge and Ge_{0.90}Si_{0.08}Sn_{0.02} layers at 700° C. is due to the inherent thermal mismatch at this temperature, we quenched the sample from 700° C. to ambient and repeated the XRD analysis. The latter revealed a single peak virtually identical to that obtained before annealing as shown in the right-most panel of FIG. 12 (a). This result indicates that the Ge/Ge_{0.90}Si_{0.08}Sn_{0.02} system follows the expected bulk-like thermoelastic response.

FIG. 12, panels (b) and (c), show plots of the expansion of the in-plane (Δa) and perpendicular (Δc) lattice constants, respectively, for the Si(100)/Ge/Ge_{0.90}Si_{0.08}Sn_{0.02} system (full stack) described in this study, the corresponding Si(100)/Ge template and the Si(100) substrate. The data in panel (b) indicate that the Δa for the Ge layer in the Si(100)/Ge template sample tracks the underlying Si up to 400° C. but expands at the same rate as the Si(100)/Ge/Ge_{0.90}Si_{0.08}Sn_{0.02} layers above this temperature. By contrast panel (c) shows that the corresponding Δc of the Si(100)/Ge template matches that of the heterostructure at all temperatures. Collectively the in-plane and perpendicular lattice dimension data indicate that the films grown on Si(100) are effectively decoupled from the Si(100) over the entire temperature range for Si(100)/Ge/Ge_{0.90}Si_{0.08}Sn_{0.02}, and above ˜400° C. for Si(100)/Ge template.

Taken together these observations indicate that the thermal expansion (CTE) of the Ge and Ge_{0.90}Si_{0.08}Sn_{0.02} layers of the heterostructures is matched up to 600° C. as shown FIG. 12(a). This is an important finding from a practical perspective. First it is well known that the CTE of Ge matches that of GaAs indicating that integration of the classic GaAs/InGaP photovoltaic multijunction on our newly developed Si(100)/Ge/Ge_{0.90}Si_{0.08}Sn_{0.02} group IV platforms can be achieved with minimal thermal stress. Most importantly, this also implies that the Ge/Ge_{0.90}Si_{0.08}Sn_{0.02} structure is perfectly stable under MOCVD growth conditions employed in typical III-V materials processing (about 550° C. to about 600° C.). In particular, in this temperature range, we find that the Ge_{0.90}Si_{0.08}Sn_{0.02} remains a single phase material with no evidence of Sn segregation or interdiffusion across the interface with the underlying Ge. This indicates that the creation of the first multijunction group IV/III-V hybrid is feasible from a growth perspective.

### Example 6

### Optical Properties of Ge_{1-x-y}SiₓSn_{y} on Ge-Buffered Substrates

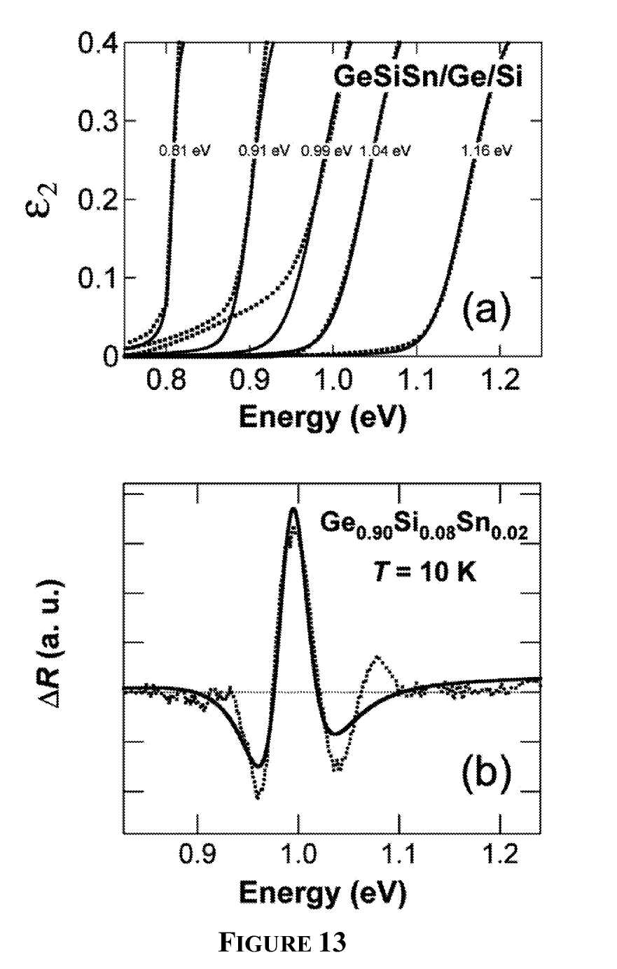

Optical studies were carried out using a variable-angle spectroscopic ellipsometer with a computer-controlled compensator (see, Herzinger et al., J. Appl. Phys. 83, 3323 (1998)). The samples were modeled as a four-layer system containing a Si substrate, the Ge buffer layer, the GeSiSn film, and a surface layer. The ellipsometric data were processed as described in D'Costa et al., Phys. Rev. B 73, 125207 (2006). This approach yields a “point-by-point” dielectric function, generated by fitting the ellipsometric angles at each wavelength to expressions containing the real and imaginary parts of the GeSiSn dielectric function as adjustable parameters, and also a parametric dielectric function obtained from a global fit to the layer thicknesses and ellipsometric angles at all wavelengths. This fit uses parameterized functional expressions for the dielectric function of tetrahedral semiconductors as developed by Johs and Herzinger (JH) (see, Johs et al., Thin Solid Films 313-314, 137 (1998)). The JH expressions contain many adjustable parameters, some of which are associated with critical points in the joint electronic density of states. We find that the two approaches are in excellent agreement, indirectly confirming the Kramers-Kronig consistency of the point-by-point fits. In FIG. 13 we show the imaginary part of the JH-dielectric function for representative samples. It is clear from the figure that the absorption edge can be displaced to energies higher than that of pure Ge while keeping the lattice parameter perfectly matched to Ge. Since Vegard's law is a very good approximation for GeSiSn alloys (see, Aella et al., Appl. Phys. Lett. 84, 888 (2004)), the compositional formula for an alloy lattice matched to Ge is Ge_{1-X}(Si_{β}Sn_{1-β})_{X} with β=0.79. Assuming that the band-gap dependence on composition is also linear, we predict for Si_{β}Sn_{1-β} a direct band gap E₀=3.14 eV, much larger than E₀=0.80 eV for pure Ge. Thus the band-gap increase as a function of X is to be expected.

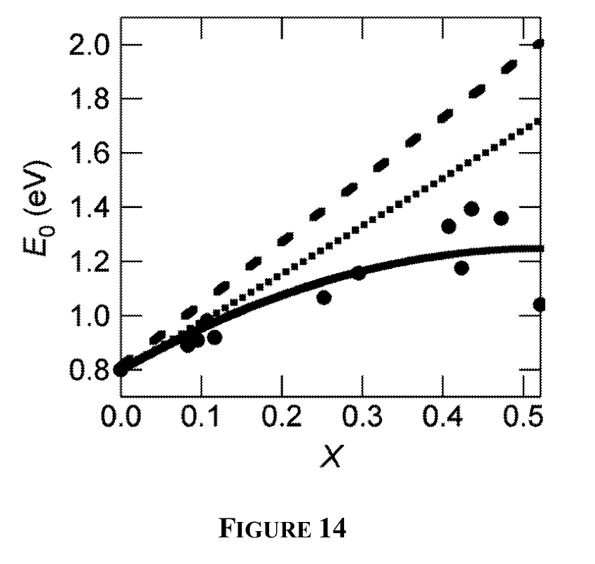

For an in-depth analysis of the GeSiSn electronic structure we must extract precise E₀ values from experiment. The standard approach to obtain optical transition energies from ellipsometric data is to compute numerical high-order derivatives of the “point-by-point” dielectric function. This method is difficult to implement in our case because the data are quite noisy near the lowest direct gap E₀. Instead, we first extract E₀ directly from the parameters in the JH model. This is a somewhat risky approach (in spite of the excellent agreement with the point-by-point dielectric function) because the values of E₀ so obtained could be affected by uncontrollable systematic errors due to the presence in the JH model of many additional parameters with unclear physical meaning. Thus we use a second approach for the determination of E₀. Regardless of the physical meaning of its individual parameters, the JH-dielectric function can be regarded as a smooth fit of the point-by-point data with a function that is Kramers-Kronig consistent. We then fit the imaginary part of the JH-dielectric function with a realistic expression for the band-edge absorption near the E₀ gap, including excitonic effects and k·p expressions for the effective masses. The only adjustable parameters of the fit are the E₀ value and phenomenological broadening parameters. For the case of pure Ge, a Lorentzian broadening is used; for the ternary alloy we use a Voigt broadening in which the Lorentzian component is fixed and equal to that of Ge. Some of these fits are shown in FIG. 13(a). Since our expressions assume parabolic bands, they are valid only very close to the band edge, but their range of validity is sufficient to fit the E₀ values. As a third way to confirm our E₀ values, we performed photoreflectance experiments on selected samples. An example is shown in FIG. 13(b). This technique reveals sharp features corresponding to the E₀ transition. The data are modeled as a combination of a 3D critical point and an excitonic oscillator. The E₀ gap values as a function of temperature merge nicely with those found from ellipsometry. The good agreement between our three methods confirms that our E₀ values are reliable. They are shown in FIG. 14 as a function of X and compared with the linear interpolation discussed above. It is apparent that there is a strong deviation from the simple prediction, indicating the presence of large nonlinear terms in the compositional dependence of E₀.

The simplest phenomenological model beyond linear interpolation assumes that the optical transition energies in Ge_{1-x-y}SiₓSn_{y} can be written as two-dimensional quadratic polynomials. For the E₀ gap, the corresponding expression is E₀=E₀^{Ge}z+E₀^{Si}x+E₀^{Sn}y−b^{GeSi}xz−b^{GeSn}yz−b^{SiSn}xy, where z=1−x−y, E₀^{Ge}(E₀^{Si}, E₀^{Sn}) is the direct band gap in pure Ge (Si, α-Sn), and b^{GeSi} (b^{GeSn}, b_{SiSn}) is the bowing parameter of the E₀ transition in binary Ge—Si (Ge—Sn, Si—Sn) alloys. Notice that at this level of approximation the nonlinear behavior in the ternary alloy is fully determined by the nonlinear terms in the underlying binary alloys. For Ge_{1-x-y}SiₓSn_{y} lattice matched to Ge, the band-gap expression can be rewritten as

E₀(X)=E₀^{Ge}+AX+BX² (1)

with

A=E₀^{Si}β+E₀^{Sn}(1−β)−E₀^{Ge}−b^{GeSi}β−b^{GeSn}(1−β) (2)

and

B=b^{GeSi}β+b^{GeSn}(1−β)−b^{SiSn}β(1−β) (3)

The linear coefficient A is determined by the elemental semiconductor band gaps and by the bowing parameters for GeSn and SiGe alloys. From D'Costa (supra), we obtain A=1.75 eV. The linear term is plotted in FIG. 14 of that reference as a dotted line, and it is seen that it is in better agreement with experiment than the simple linear interpolation (shown by dashed line), but it still overestimates the observed E₀ values. This implies that B is negative, and from Eq. (3) we conclude that b^{SiSn}>3.4 eV. If we fit the band-gap values with Eq. (1), using A and B as adjustable parameters, we obtain A=1.70±0.42, in excellent agreement with our prediction, and B=−1.62±0.96, which implies a very large b^{SiSn}=13.2 eV. Of course, this conclusion depends on our assumption that the compositional dependence of the band gap is quadratic. It is in principle possible that the large bowing arises from higher-order terms. For example, a large contribution proportional to xyz, which vanishes for the binary alloys, could be the explanation for the negative B. However, there are reasons to believe that a large b^{SiSn} makes a significant contribution to the quadratic coefficient B. Calculations for binary Si_{1-y}Sn_{y} alloys [14] show a large and compositional dependent bowing parameter, ranging from b^{SiSn}=14 eV for y=0.2 to b^{SiSn}=4 eV for y=0.5. Previous results on the compositional dependence of the E₁ transition in GeSiSn alloys could be explained by assuming that the bowing parameters for the binary Si—Ge, Ge—Sn, and Si—Sn alloys scale according to the lattice constant and Phillips electronegativity mismatch (see, D'Costa et al., Solid State Commun. 138, 309 (2006)). For the E₀ transition, we have b^{SiGe}=0.21 and b^{Gesn}=1.94 eV, from which we predict b^{SiSn}=3.26 eV. This is comparable to the value b^{SiSn}=4 eV for y=0.5 found from supercell calculations (see, Tolle et al., Appl. Phys. Lett. 89, 231924 (2006)). The corresponding band edge states show considerable dispersion and do not appear to be impurity-like. We conjecture that the much higher bowing found for y=0.2 signals the transition to an impurity-like regime associated with more localized states. This behavior is similar to that computed for GaAs₁₋ₓNₓ compounds by Wei and Zunger (Phys. Rev. Lett. 76, 664 (1996)) who invoked the localized character of the conduction band wave functions to explain the origin of anomalous bowing behavior in the band gap.

In summary, we find that the direct-gap absorption edge in ternary GeSiSn alloys lattice-matched to Ge can be tuned over the 0.8 eV-1.4 eV range. Research in photovoltaics has identified a hypothetical 1-eV gap material lattice-matched to Ge as the most promising route to improve the performance of multijunction solar cells based on the Ge/InGaAs/InGaP system. Our alloys meet these two fundamental requirements, and may have important applications in this field. The analysis of the compositional dependence of the direct band gap yields a very rich phenomenology unique to ternary alloys. This includes the coexistence of small and large bowing parameters, which probably implies that the nature of the band-edge states can also be tuned from bandlike to impuritylike by proper adjustment of the alloy composition.

### Example 7

### N- and P-Doping of GeSiSn

We achieved the fabrication of B and P doped SiGeSn ternaries, lattice-matched to Ge, with compositions adjusted to independently tune the bandgap. These materials are deposited at 320° C.-350° C. with superior crystallinity and morphology via in-situ reactions of diborane (p-type) and designer P(SiH₃)₃ and P(GeH₃)₃ precursors (n-type). Device-level carrier concentrations ranging from about 10¹⁹/cm³ to about-10²⁰/cm³ are routinely produced yielding film resistivities and carrier mobilities comparable to those of Ge indicating negligible alloy scattering (see Table 1). An important highlight of the research was that the high boron levels induce a significant and systematic contraction of the host SiGeSn lattice which is compensated by an adjustment of the Si/Sn ratio in accord with a simple model based on Vegrad's Law and covalent radii of the constituents. The structural data suggest that the SiₓSn_{y}Ge_{1-x-y-z}B_{z} behaves in essence like a pseudo quaternary alloy involving dilute compositions of group III elements in a group IV matrix.

TABLE 1
Boron concentration (N), resistivity (ρ) and mobility
(μ) dependence in three typical samples containing
the target contents of ~2%, 5% and 8% Sn.

| Sn % | N (×10²⁰ cm⁻³) | ρ(×10⁻⁴ Ω · cm) | μ(cm²/V s) |
|---|---|---|---|
| 2.5 | 0.5 (0.4) | 6.6 (10.4) | 186 (144) |
| 5-5.5 | 2.1 (1.1) | 3.8 (5.7) | 80 (98) |
| 8 | 1.1 (0.7) | 4.7 (10.7) | 124 (85) |

### Example 8

### Growth of GaAs and InGaAs on Ge/SiGeSn Platforms

The prior examples established that the Ge/SiGeSn films grown upon Si are ideally suited in terms of structure, thermal stability and optical response to be used in the subsequent growth of the proposed high-efficiency III-V photovoltaic structure. We explored the direct growth of the InGaAs component as the next step in the formation of the entire Si(100)/Ge/SiGeSn/InGaAs/InGaP stack. InₓGa₁₋ₓAs alloys span a wide range of lattice constants and display monotonically decreasing band gaps between those of GaAs (5.65 Å, 1.42 eV) and InAs (6.058 Å, 0.354 eV). In state-of-the-art solar cell applications InₓGa₁₋ₓAs layers with to x≦0.02 have been obtained on both bulk Ge and GaAs substrates. In our own previous work we have shown that lattice engineered Ge_{1-y}Sn_{y} buffer layers with concentrations y=0.02-0.08 and lattice parameters between 5.68 Å and 5.73 Å can be used to successfully fabricate InₓGa₁₋ₓAs alloys with variable and controllable stoichiometries directly on Si substrates (see, Roucka et al., J. Appl. Phys. 2007, 101, 013518). The latter materials showed much less strain than those grown on conventional substrates such as Ge and GaAs and displayed high quality morphological and structural properties as indicated by their optical properties, which compared well with those measured in fully relaxed micrometer thick layers grown on bulk GaAs. The increased lattice constant of Ge_{1-y}Sn_{y} relative to the Ge and GaAs make it possible to form higher indium content InₓGa₁₋ₓAs with much less strain leading to improved performance.

A unique feature of the above Ge_{1-y}Sn_{y} buffer layer approach is that the surface preparation for subsequent epitaxy of InₓGa₁₋ₓAs is trivial and straightforward in comparison to conventional Ge or Si substrates. In the present solar cell application the low Si-content Si_{0.08}Ge_{0.90}Sn_{0.02} surface can also be prepared using a virtually identical chemical cleaning method. This further demonstrates the viability of the ternary materials as versatile templates for integration of the III-V solar cell components with Si substrates.

In all deposition experiments the Si(100)/Ge/SiGeSn substrates were initially cleaned in an acetone/methanol ultrasonic bath, dipped in a dilute HF solution (1%) for 1 minute, blow-dried and then loaded in the growth chamber and outgased until the pressure reached the base value of ˜10⁻⁸ Torr. The reactor is a horizontal low-pressure, cold-wall system fitted with a load-lock and an inductively heated molybdenum block susceptor. A combination of a high capacity turbo pump and a cryo pump is used to achieve UHV conditions thereby ensuring extremely low levels of background impurities. Prior to deposition the samples were briefly exposed to a flow of arsine gas (diluted in high purity H₂) at ˜500° C. to remove any residual contaminants from their surface. The growth of the InₓGa₁₋ₓAs layer is conducted immediately thereafter via reactions Ga(CH₃)₃ (trimethylgallium), In(CH₃)₃ (trimethylindium) and AsH₃ (arsine). Stock mixtures of Ga(CH₃)₃ and AsH₃ with H₂ in 1:10 and 1:15 ratios, respectively, were employed and their relative concentrations during deposition were regulated by mass flow controllers. The solid In(CH₃)₃ compound was dispensed from a glass bubbler using H₂ as a carrier gas and the specific amount of the material was regulated by its vapor pressure and the H₂ flow rate. A typical deposition was conducted at 550° C. and 50 Torr for 10-15 minutes yielding nominal growth rates of 20 nm per minute. After growth, the films were slowly cooled to room temperature under a continuous flow of AsH₃ to prevent evaporation of elemental arsenic from the surface layers. Under these conditions, smooth and continuous films were obtained with no evidence of In or Ga metal droplets or surface pits. The samples were thoroughly analyzed by RBS, AFM, XTEM and HRXRD to determine composition, morphology, microstructure and crystallographic quality.

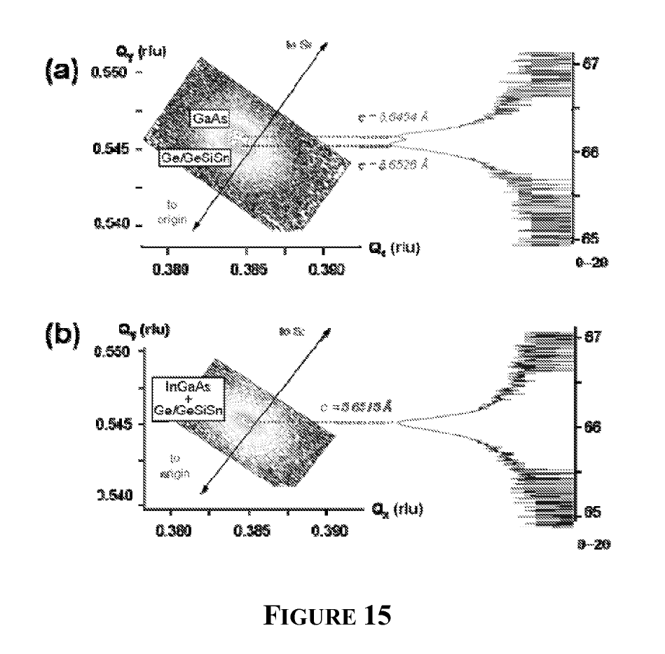

FIG. 15 shows high resolution XRD data for a Ge/SiGeSn/InGaAs film grown on Si and it is compared to a corresponding Ge/SiGeSn/GaAs sample. The later was prepared during the initial stage of this study for the purpose of establishing optimum growth protocols. The (224) reciprocal space maps show two distinct peaks associated with the Ge/SiGeSn and GaAs layers respectively. The SiGeSn lattice dimensions perfectly match those of the underlying Ge layer and together the Ge/SiGeSn stack imposes a slight tensile strain in the mismatched GaAs overlayer. This is shown in the figure by the position of the line connecting the Si (224) peak with the origin which passes slightly below the center of the GaAs (224) spot. In contrast, the corresponding RSM plot for the Ge/SiGeSn/InGaAs sample shows only one peak indicating that the addition of a minor indium content (2 at %) is sufficient to relieve the strain differential and yield a perfectly lattice-matched Ge/SiGeSn/InGaAs stack for the fabrication of the photovoltaic device. Precise measurements of the lattice constants for the entire stack using the (224) and (004) reflections give a=5.660 Å, c=5.6515 Å, which confirm that the layers are fully lattice matched and exhibit only a residual tensile strain which is likely due to the thermal cycling during the fabrication of the stack.

The RBS spectra (not shown) of a typical lattice-matched InₓGa₁₋ₓAs film grown on Ge/Ge_{0.90}Si_{0.08}Sn_{0.02} comprises of overlapping peaks corresponding to the signals of Ge, Sn, Ga, As, and In. A data fitting procedure using the known buffer layer composition and thickness reveals that the corresponding thickness and stoichiometry of the epilayer are 200-600 nm and In_{0.02}Ga_{0.98}As, respectively. The ion channeling spectrum shows a high degree of crystallinity and epitaxial alignment between the various InGaAs, SiGeSn and Ge components of the film and the underlying Si(100) substrate. The χₘᵢₙ value of the Sn signal is virtually identical before and after InGaAs deposition, indicating that the Ge_{0.90}Si_{0.08}Sn_{0.02} buffer is thermally robust under these processing conditions with the entire Sn content remaining substitutional. Finally we note that the χₘᵢₙ values for In, Ga and As in the epilayer are nearly equal (about 3 to about 6%) indicating that these atoms all occupy equivalent lattice sites in the alloy consistent with single phase material.

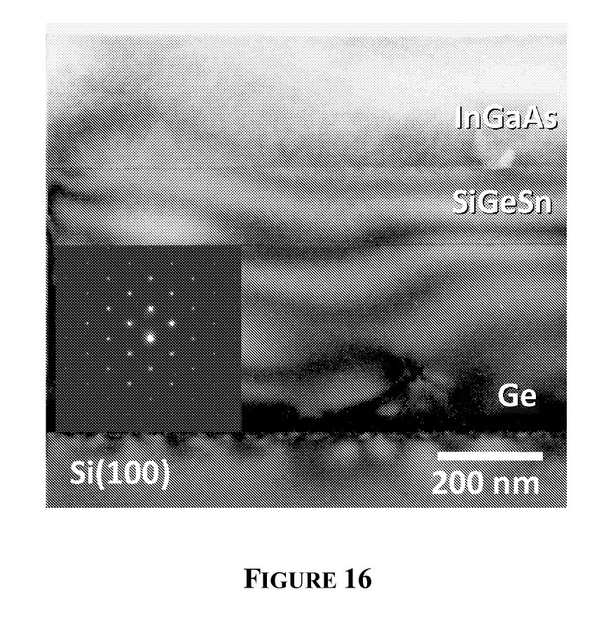

AFM studies of both Ge/SiGeSn/GaAs and Ge/SiGeSn/InGaAs samples show a fairly smooth surface with RMS values of ˜5 nm. XTEM analysis of these materials reveals single-phase layers in perfect epitaxial alignment. Bright field micrographs of the entire heterostructure and high-resolution images of the epilayer-buffer interface show high quality microstructure and morphology, including sharp, defect-free interfaces and planar surfaces. Occasional dislocations penetrating to the surface are observed in the bright field images. A XTEM micrograph of a representative Si/Ge/Si_{0.08}Ge_{0.90}Sn_{0.02}/InGaAs structure showing the entire sequence of the constituent layers is presented in FIG. 16. The thicknesses measured here are in close agreement with those determined by RBS.

The above-described invention possesses numerous advantages as described herein and in the referenced appendices. The invention in its broader aspects is not limited to the specific details, representative devices, and illustrative examples shown and described. Accordingly, departures may be made from such details without departing from the spirit or scope of the general inventive concept.

We claim:

1. A semiconductor structure comprising
(i) a Si substrate;
(ii) a buffer region formed directly over the Si substrate, wherein the buffer region comprises
(a) a Ge layer having a threading dislocation density below about 10⁵/cm², wherein the Ge layer is formed directly over the Si substrate; or
(b) a Ge₁₋ₓSnₓ layer formed directly over the Si substrate and a Ge_{1-x-y}SiₓSn_{y} layer formed over the Ge₁₋ₓSnₓ layer; and
(iii) a plurality of III-V active blocks formed over the buffer region.

2. The semiconductor structure of claim 1, wherein the buffer region comprises a Ge layer having a threading dislocation density below 10⁵/cm².

3. The semiconductor structure of claim 2, wherein the Ge layer has a thickness of greater than about 5 μm.

4. The semiconductor structure of claim 2, wherein the Ge layer has a thickness of about 0.1 μm to about 1.0 μm.

5. The semiconductor structure of claim 1, wherein the buffer region comprises at least one active block.

6. The semiconductor structure of claim 1 wherein the buffer region comprises a first active block comprising the Ge layer having a threading dislocation density below 10⁵/cm², wherein the Ge layer is formed directly over the Si substrate.

7. The semiconductor structure of claim 6, wherein the buffer region further comprises a second active block comprising a Ge_{1-x-y}SiₓSn_{y} layer lattice matched or pseudomorphically strained to the first active block formed over the first active block.

8. The semiconductor structure of claim 7, wherein x and y for the Ge_{1-x-y}SiₓSn_{y} layer are in a ratio of about 3:1 to about 5:1.

9. The semiconductor structure of claim 7, wherein the Ge_{1-x-y}SiₓSn_{y} layer has a bandgap of about 0.80 eV to about 1.40 eV.

10. (canceled)

11. The semiconductor structure of claim 9 wherein the Ge_{1-x-y}SiₓSn_{y} layer comprises an alloy the formula, Ge_{1-X}(Si_{β}Sn_{1-β})_{X} wherein β is about 0.79 and X is a value greater than 0 and less than 1.

12. The semiconductor structure of claim 9 wherein the second active block comprises a Ge_{1-x-y}SiₓSn_{y} alloy, lattice matched or pseudomorphically strained to Ge, wherein x is about 0.07 to about 0.42 and y is about 0.01 to about 0.20.

13. (canceled)

14. The semiconductor structure of claim 1 wherein the buffer region comprises a Ge₁₋ₓSnₓ layer formed directly over the Si substrate and a Ge_{1-x-y}SiₓSn_{y} layer formed over the Ge₁₋ₓSnₓ layer.

15. The semiconductor structure of claim 14, wherein the buffer region comprises a Ge₁₋ₓSnₓ layer formed directly over the Si substrate and a first active block comprising the Ge_{1-x-y}SiₓSn_{y} layer formed over the Ge₁₋ₓSnₓ layer.

16. (canceled)

17. The semiconductor structure of claim 15 wherein the first active block comprises a p-n or p-i-n junction.

18. The semiconductor structure of claim 15 wherein the first active block comprises a Ge_{1-x-y}SiₓSn_{y} alloy, lattice matched or pseudomorphically strained to Ge, wherein x is about 0.19 to about 0.37 and y is about 0.02 to about 0.12.

19. The semiconductor structure of claim 15 wherein the first active block comprises a Ge_{1-x-y}SiₓSn_{y} alloy, lattice matched or pseudomorphically strained to Ge, having a bandgap of about 0.80 eV to about 1.40 eV.

20. The semiconductor structure of claim 15 wherein the first active block comprises a Si_{0.075}Ge_{0.905}Sn_{0.02}, Si_{0.08}Ge_{0.90}Sn_{0.02}, Si_{0.19}Ge_{0.76}Sn_{0.05}, Si_{0.20}Ge_{0.745}Sn_{0.055}, Si_{0.23}Ge_{0.71}Sn_{0.06}, Si_{0.26}Ge_{0.67}Sn_{0.07}, Si_{0.30}Ge_{0.60}Sn_{0.10}, Si_{0.31}Ge_{0.60}Sn_{0.09}, Si_{0.32}Ge_{0.64}Sn_{0.04}, or Si_{0.41}Ge_{0.48}Sn_{0.11}, Si_{0.27}Ge_{0.56}Sn_{0.17} alloy, each lattice matched or pseudomorphically strained to the Ge layer.

21. The semiconductor structure of claim 14, wherein the buffer region comprises a first active block comprising the Ge₁₋ₓSnₓ layer formed directly over the Si substrate and a second active block comprising a Ge_{1-x-y}SiₓSn_{y} layer, wherein the second active block is formed over the first active block.

22. The semiconductor structure of claim 21, wherein the first active block and second active block independently comprise a p-n or p-i-n junction.

23. The semiconductor structure of claim 21 the Ge₁₋ₓSnₓ layer comprises a Ge₁₋ₓSnₓ alloy, wherein x is about 0.01 to about 0.20.

24. (canceled)

25. (canceled)

26. (canceled)

27. The semiconductor structure of claim 1 wherein each III-V active block comprises a p-n or p-i-n junction.

28. The semiconductor structure of claim 27, wherein each III-V active block comprises a binary, tertiary, quaternary, or higher (InGaAl)(AsSbP) semiconductor.

29. (canceled)

30. (canceled)

31. (canceled)

32. (canceled)

33. A method for forming a semiconductor structure comprising
forming a buffer region directly over a Si substrate; and
forming a plurality of III-V active blocks over the buffer region, wherein the buffer region comprises
(a) a Ge layer having a threading dislocation density below 10⁵/cm² and a Ge_{1-x-y}SiₓSn_{y} layer formed over the Ge layer, wherein the Ge layer is formed directly over the Si substrate; or
(b) a Ge₁₋ₓSnₓ layer and a Ge_{1-x-y}SiₓSn_{y} layer formed over the Ge₁₋ₓSnₓ layer, wherein the Ge₁₋ₓSnₓ layer is formed directly over the Si substrate.

34. The method of claim 33, wherein the buffer region and/or the plurality of III-V active blocks are each independently formed by source molecular beam epitaxy, chemical vapor deposition, plasma enhanced chemical vapor deposition, laser assisted chemical vapor deposition, and atomic layer deposition.

35. The method of claim 34, wherein each of the layers of the buffer region are prepared by CVD using digermane, silylgermane, trisilane, stannane, or mixtures thereof.

36. The method of claim 35, wherein the Si:Sn concentration in each layer is tuned by reaction of trisilane and stannane as the sources of Si and Sn respectively.

37. (canceled)

38. (canceled)

39. (canceled)

40. The method of any one of claim 38 wherein the Ge_{1-x-y}SiₓSn_{y} layers are formed by contacting the Ge₁₋ₓSnₓ layer with a chemical vapor comprising (i) H₃SiGeH₃ or SiH₃SiH₂SiH₃; and (ii) SnD₄.

41. A Ge_{1-x-y}SiₓSn_{y} alloy, lattice matched or pseudomorphically strained to Ge, wherein x is about 0.07 to about 0.42 and y is about 0.01 to about 0.20.

42. (canceled)

43. (canceled)

44. (canceled)

45. (canceled)

46. A Ge_{1-x-y}SiₓSn_{y} alloy, lattice matched or pseudomorphically strained to Ge, having a bandgap of about 0.80 eV to about 1.40 eV.

47. (canceled)

48. The Ge_{1-x-y}SiₓSn_{y} alloy of claim 46 wherein x is about 0.07 to about 0.42 and y is about 0.02 to about 0.20.

49. (canceled)

50. The Ge_{1-x-y}SiₓSn_{y} alloy of claim 48 wherein y is about 0.02 to about 0.12.

51. (canceled)

52. A GeSiSn alloy of the formula, Ge_{1-X}(Si_{β}Sn_{1-β})_{X} wherein β is about 0.79 and X is a value greater than 0 and less than 1.
